(19) United States
(12) Patent Application Publication
(10) Pub. No.: US 2025/0048667 A1
(43) Pub. Date: Feb. 6, 2025

(54) SEMICONDUCTOR DEVICE WITH GATE ELECTRICAL CONTACT FORMING JUNCTIONS HAVING DIFFERENT ENERGY BARRIER HEIGHTS TO GATE LAYER

(71) Applicant: TEXAS INSTRUMENTS INCORPORATED, Dallas, TX (US)

(72) Inventors: Ujwal Radhakrishna, San Jose, CA (US); Zhikai Tang, Sunnyvale, CA (US); Johan Strydom, Saratoga, CA (US); Jungwoo Joh, Allen, TX (US)

(21) Appl. No.: 18/361,997

(22) Filed: Jul. 31, 2023

(51) Int. Cl. H01L 29/778; H01L 29/40; H01L 29/423; H01L 29/45; H01L 29/47; H01L 29/872

(52) U.S. Cl. CPC H01L 29/778; H01L 29/401; H01L 29/42316; H01L 29/452; H01L 29/475; H01L 29/7786; H01L 29/872; H01L 29/2003

(57) ABSTRACT

The present disclosure generally relates to a semiconductor device that includes a gate electrical contact that forms junctions with different energy barrier heights to a gate layer. In an example, a semiconductor device includes a semiconductor substrate, a drain electrical contact, a source electrical contact, a barrier layer, a gate layer, and a gate electrical contact. The drain and source electrical contacts are on the semiconductor substrate. The barrier layer is over a channel region of the semiconductor substrate between the drain and source electrical contacts. The gate layer is over the barrier layer. The gate layer includes first and second semiconductor portions. The gate electrical contact contacts the gate layer. The gate electrical contact includes first and second metal portions. The first and second metal portions form first and second junctions with the first and second semiconductor portions, respectively. The first and second junctions have different energy barrier heights.

### BACKGROUND

A type of semiconductor device is a high electron mobility transistor (HEMT). A HEMT typically employs different semiconductor materials to form a heterojunction, where a channel may be formed near the heterojunction and between a source region and a drain region. A HEMT may have a high speed operation, which makes HEMTs attractive for high frequency applications, among others.

### SUMMARY

This Summary is provided to introduce a brief selection of disclosed concepts in a simplified form that are further described below in the Detailed Description including the drawings provided. Various disclosed devices and methods may be beneficially applied to a semiconductor device that includes a gate electrical contact that forms junctions with different energy barrier heights to a gate layer. While such embodiments may be expected to achieve low gate leakage, stabilized gate overdrive voltage (V_{GT}), and increased drain current (I_{d}), no particular result is a requirement unless explicitly recited in a particular claim.

An example described herein is a semiconductor device. The semiconductor device includes a semiconductor substrate, a drain electrical contact, a source electrical contact, a barrier layer, a gate layer, and a gate electrical contact. The drain electrical contact is on the semiconductor substrate, and the source electrical contact is on the semiconductor substrate. The barrier layer is over a channel region of the semiconductor substrate between the drain electrical contact and the source electrical contact. The gate layer is over the barrier layer. The gate layer includes a first semiconductor portion and a second semiconductor portion. The gate electrical contact contacts the gate layer. The gate electrical contact includes a first metal portion and a second metal portion. The first metal portion forms a first junction with the first semiconductor portion, and the second metal portion forms a second junction with the second semiconductor portion. The first junction and the second junction have different energy barrier heights.

Another example is a method. A patterned gate layer is formed over a barrier layer. The barrier layer is over a channel layer over a semiconductor substrate. The patterned gate layer includes a first semiconductor portion and a second semiconductor portion. A gate electrical contact is formed contacting the patterned gate layer. The gate electrical contact includes a first metal portion and a second metal portion. A first energy barrier height is of a junction between the first metal portion and the first semiconductor portion, and a second energy barrier height is of a junction between the second metal portion and the second semiconductor portion. The first energy barrier height is greater than the second energy barrier height.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

FIG. 1 illustrates a cross-sectional view of an enhancement mode high electron mobility transistor (HEMT) with an overlaid circuit model of the HEMT.

FIG. 2 illustrates a cross-sectional view of an enhancement mode HEMT with an overlaid circuit model of the HEMT according to some examples.

FIGS. 3, 4, and 5 are cross-sectional views of respective semiconductor devices according to some examples.

FIGS. 6, 7, 8, and 9 are perspective views of respective semiconductor devices according to some examples.

FIG. 10 is a layout view of a semiconductor device according to some examples.

FIGS. 11, 12, and 13 are cross-sectional views of respective semiconductor devices according to some examples.

FIGS. 14 and 15 are perspective views of respective semiconductor devices according to some examples.

FIG. 16 is a cross-sectional view of a semiconductor device according to some examples.

FIG. 17 is a perspective view of a semiconductor device according to some examples.

FIGS. 18 and 19 are cross-sectional views of respective semiconductor devices according to some examples.

FIG. 20 is a flowchart of a method of manufacturing the semiconductor device of FIG. 3 according to some examples.

FIGS. 21, 22, 23, 24, 25, and 26 are cross sectional views of the semiconductor device of FIG. 3 at various stages of manufacturing according to some examples.

FIG. 27 is a flowchart of a method of manufacturing the semiconductor device of FIG. 4 according to some examples.

FIGS. 28, 29, 30, 31, and 32 are cross sectional views of the semiconductor device of FIG. 4 at various stages of manufacturing according to some examples.

FIG. 33 is a flowchart of a method of manufacturing the semiconductor device of FIG. 5 according to some examples.

FIGS. 34, 35, 36, 37, and 38 are cross sectional views of the semiconductor device of FIG. 5 at various stages of manufacturing according to some examples.

FIG. 39 is a flowchart of a method of manufacturing the semiconductor device of FIG. 11 according to some examples.

FIGS. 40, 41, and 42 are cross sectional views of the semiconductor device of FIG. 11 at various stages of manufacturing according to some examples.

FIG. 43 is a flowchart of a method of manufacturing the semiconductor device of FIG. 12 according to some examples.

FIGS. 44, 45, 46, 47, and 48 are cross sectional views of the semiconductor device of FIG. 12 at various stages of manufacturing according to some examples.

FIG. 49 is a flowchart of a method of manufacturing the semiconductor device of FIG. 13 according to some examples.

FIGS. 50, 51, 52, and 53 are cross sectional views of the semiconductor device of FIG. 13 at various stages of manufacturing according to some examples.

FIG. 54 is a flowchart of a method of manufacturing the semiconductor device of FIG. 16 according to some examples.

FIGS. 55, 56, and 57 are cross sectional views of the semiconductor device of FIG. 16 at various stages of manufacturing according to some examples.

FIG. 58 is a flowchart of a method of manufacturing the semiconductor device of FIG. 18 according to some examples.

FIGS. 59, 60, and 61 are cross sectional views of the semiconductor device of FIG. 18 at various stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to a semiconductor device that includes a gate electrical contact that forms junctions with different energy barrier heights to a gate layer. In some examples described herein, the semiconductor device is a high electron mobility transistor (HEMT), such as an enhancement mode HEMT. The junctions with the different energy barrier heights may permit the semiconductor device to achieve low gate leakage, stabilized gate overdrive voltage (V_{GT}), and increased drain current (I_{d}). Other benefits and advantages may be achieved.

Various examples are described herein. Although the specific examples may illustrate various aspects of the above generally described features, examples may incorporate any combination of the above generally described features (which are described in more detail in examples below). Three dimensional x-y-z axes are illustrated in some figures for case of reference. Some cross-sectional views of various semiconductor devices herein may be general depictions to communicate various aspects or concepts concerning such semiconductor devices. More specifically, some gate electrical contacts illustrated in cross-sectional views may not necessarily accurately depict a structure of such gate electrical contacts, except to the extent described herein. The illustrations of those gate electrical contacts is to communicate various aspects or concepts concerning those gate electrical contacts.

Various examples are described in the context of a HEMT. Some examples may be implemented in enhancement mode lateral HEMTs that are for high voltage (e.g., 650 V to 1,200 V) applications or low to medium voltage (e.g., 10 V to 100 V or 10 V to 200 V) applications. In other examples, the semiconductor device may be or include a bidirectional field effect transistor (FET), a gated Schottky barrier diode (e.g., gate-to-drain shorted structure or gate-to-source shorted structure), or similar devices. Although various methods of forming a semiconductor device are described herein, some examples may be implemented in a gate-first or a replacement gate process and may be implemented in a self-aligned or non-self-aligned process. Some examples may be implemented with any epitaxial structure, any field plate and/or ohmic contact procedure, a planar or three-dimensional structure (e.g., fin structure), and/or various other modifications.

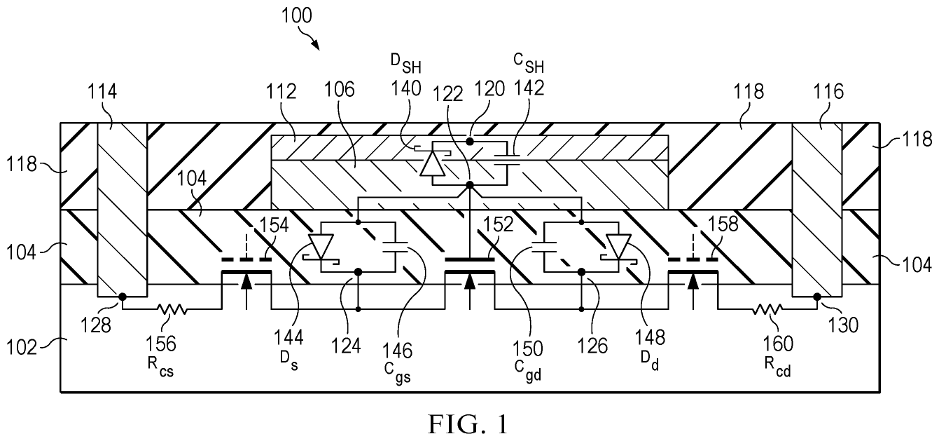

FIG. 1 illustrates a cross-sectional view of an enhancement mode HEMT 100 with an overlaid circuit model of the HEMT 100. The HEMT 100 includes a channel layer 102, a barrier layer 104 over the channel layer 102, and a gate layer 106 over the barrier layer 104. The configuration of the barrier layer 104 over the channel layer 102 forms a two-dimensional electron gas (2DEG) in the channel layer 102 near the interface between the channel layer 102 and the barrier layer 104. A gate electrical contact 112 is over and on the gate layer 106. In this illustration, the gate electrical contact 112 and the gate layer 106 form a Schottky junction, which may result from a metal of the gate electrical contact 112 and/or doping of the gate layer 106. A source electrical contact 114 and a drain electrical contact 116 are electrically coupled to the channel layer 102 on opposing sides of the gate layer 106. A dielectric layer 118 is over and on the barrier layer 104, the gate layer 106, and the electrical contacts 112, 114, 116.

Referring to the circuit model, a gate contact node 120 is in the gate electrical contact 112, and a gate layer node 122 in in the gate layer 106. A channel source-side node 124 and a channel drain-side node 126 are at an interface between the channel layer 102 and the barrier layer 104. A source contact node 128 is in the source electrical contact 114, and a drain contact node 130 is in the drain electrical contact 116.

A Schottky diode (D_{SH}) 140 and a Schottky capacitor (C_{SH}) 142 are electrically coupled between the gate contact node 120 and the gate layer node 122. A cathode terminal of the Schottky diode 140 is electrically coupled to the gate contact node 120, and an anode terminal of the Schottky diode 140 is electrically coupled to the gate layer node 122. Similarly, a first terminal of the Schottky capacitor 142 is electrically coupled to the gate contact node 120, and a second terminal (opposite from the first terminal) of the Schottky capacitor 142 is electrically coupled to the gate layer node 122.

A p-type, intrinsic, n-type (p-i-n) source-side diode (Dₛ) 144 and a gate-to-source capacitor (C_{gs}) 146 are electrically coupled between the gate layer node 122 and the channel source-side node 124. An anode terminal of the source-side diode 144 is electrically coupled to the gate layer node 122, and a cathode terminal of the source-side diode 144 is electrically coupled to the channel source-side node 124. Also, a first terminal of the gate-to-source capacitor 146 is electrically coupled to the gate layer node 122, and a second terminal (opposite from the first terminal) of the gate-to-source capacitor 146 is electrically coupled to the channel source-side node 124.

A p-i-n drain-side diode (D_{d}) 148 and a gate-to-drain capacitor (C_{gd}) 150 are electrically coupled between the gate layer node 122 and the channel drain-side node 126. An anode terminal of the drain-side diode 148 is electrically coupled to the gate layer node 122, and a cathode terminal of the drain-side diode 148 is electrically coupled to the channel drain-side node 126. Similarly, a first terminal of the gate-to-drain capacitor 150 is electrically coupled to the gate layer node 122, and a second terminal (opposite from the first terminal) of the gate-to-drain capacitor 150 is electrically coupled to the channel drain-side node 126.

A field effect transistor (FET) 152 has a gate terminal electrically coupled to the gate layer node 122. The FET 152 has a source terminal electrically coupled to the channel source-side node 124 and has a drain terminal electrically coupled to the channel drain-side node 126. A channel of a FET 154 and a channel-to-source resistor (R_{cs}) 156 are serially electrically coupled between the channel source-side node 124 and the source contact node 128. A channel of a FET 158 and a channel-to-drain resistor (R_{cd}) 160 are serially electrically coupled between the channel drain-side node 126 and the drain contact node 130.

Having the Schottky junction between the gate electrical contact 112 and the gate layer 106 (shown by the Schottky diode 140 and Schottky capacitor 142 coupled between the gate contact node 120 and the gate layer node 122) may result in low gate leakage current during operation of the HEMT 100. A positive voltage applied on the gate electrical contact 112 (e.g., the gate contact node 120) reverse biases the Schottky junction, which may result in low gate leakage current. However, the Schottky junction between the gate electrical contact 112 and the gate layer 106 results in a back-to-back diode configuration at the gate layer node 122 (e.g., anode terminals of the Schottky diode 140 and the source-side diode 144 are electrically coupled to the gate layer node 122). Such a back-to-back diode configuration results in a floating, quasi-neutral node (e.g., the gate layer node 122) in the gate layer 106 under some circumstances. Under direct current (DC) conditions, the node in the gate layer 106 is in a voltage divider formed by the diodes 140, 144, which reduces the effective gate overdrive voltage (V_{GT}) applied on the gate layer 106, reduces drain current (I_{d}), and increases drain-to-source on resistance (R_{DSON}). In switching events, the node in the gate layer 106 may be biased based on past switching events due to its floating nature. This biasing may result in non-deterministic behavior of the HEMT 100 and may adversely affect the drain current of the HEMT 100. Further, when switching on, the Schottky capacitor 142 may form a low impedance path initially, which may quickly pull the voltage of the gate layer node 122 up to the voltage applied on the gate contact node 120. However, following the initial switching on, the voltage of the gate layer node 122 settles to some voltage proportional to the voltage applied on the gate electrical contact 112 due to the voltage divider. This voltage change at the gate layer node 122 may result in an initial peak of the drain current, with the drain current subsequently reducing and settling. Hence, the HEMT 100 may experience dynamic gate overdrive voltage (V_{GT}).

To address such adverse effects, examples described herein provide for a gate electrical contact that includes a first metal portion and a second metal portion. The first metal portion forms a first junction with a first semiconductor portion of a gate layer, and the second metal portion forms a second junction with a second semiconductor portion of the gate layer. An energy barrier height of the first junction is greater than the energy barrier height of the second junction. For example, the first junction may be a high energy barrier height Schottky junction, and the second junction may be a low energy barrier height Schottky junction or ohmic junction.

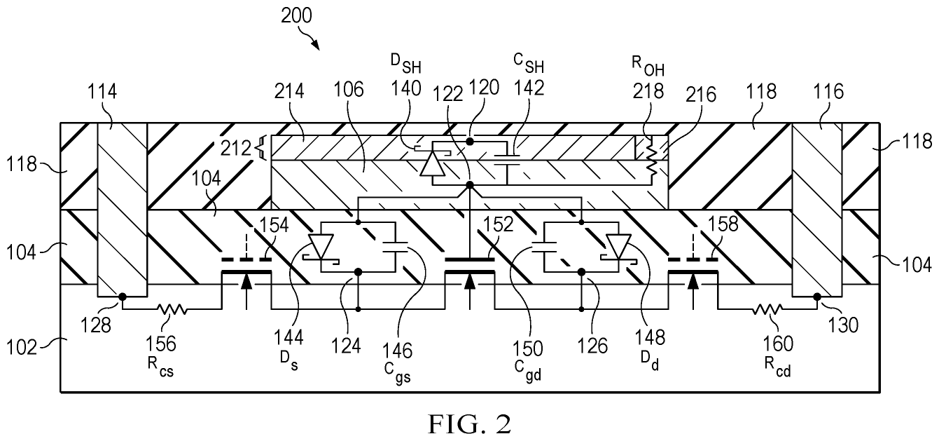

FIG. 2 illustrates a cross-sectional view of an enhancement mode HEMT 200 with an overlaid circuit model of the HEMT 200. The HEMT 200 of FIG. 2 includes at least some of the components of HEMT 100 and a gate electrical contact 212. The gate electrical contact 212 includes a first metal portion 214 and a second metal portion 216. The first metal portion 214 forms a first junction with a portion of the gate layer 106, such as the Schottky junction described above. The second metal portion 216 forms a second junction with another portion of the gate layer 106, which, as illustrated is an ohmic junction, although a low energy barrier height junction may be formed. An ohmic junction is formed between the first metal portion 214 and the second metal portion 216, which may cause the first metal portion 214 and the second metal portion 216 to remain at a same potential.

In the circuit model in FIG. 2, an ohmic resistor (R_{OH}) 218 is electrically coupled between the gate contact node 120 and the gate layer node 122. The ohmic resistor 218 is formed by the junction between the second metal portion 216 and the second semiconductor portion of the gate layer 106. The ohmic junction or low energy barrier height junction may provide a path by which the gate layer node 122 (e.g., the gate layer 106) is biased by the voltage applied to the gate electrical contact 212 and may reduce the voltage drop between the gate electrical contact and gate layer node 122. The voltage drop can be the same under DC condition and in switching events. Accordingly, the gate overdrive voltage (V_{GT}) can be increased (under DC condition) and stabilized (in switching events), and the drain current (I_{d}) can also be increased. Accordingly, the gate layer 106 may be driven to a voltage that more accurately and precisely tracks the voltage at gate electrical contact 112, which may avoid peaky current responses in switching. The surface areas of the first junction and the second junction may be scaled to obtain a target gate leakage while obtaining the stabilized gate overdrive voltage (V_{GT}) and increased drain current (I_{d}). For example, by having a surface area of the second junction being relatively small compared to the surface area of the first junction, gate leakage may remain low, while still providing a path to bias the gate layer 106 to achieve stabilized gate overdrive voltage (V_{GT}) and increased drain current (I_{d}).

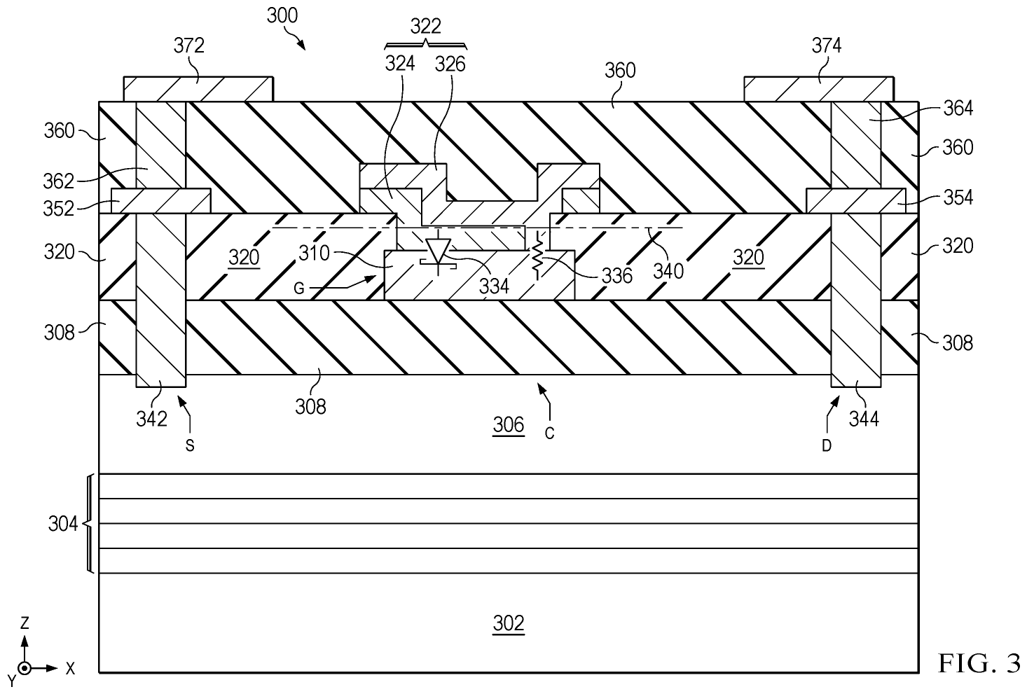

FIG. 3 illustrates a cross-sectional view of a semiconductor device 300 according to some examples. The semiconductor device 300, in this example, is or includes a HEMT. Further, the semiconductor device 300 may be or include an enhancement mode HEMT. Other examples may be or include other types of devices. FIG. 3 also includes circuit symbols overlaid on the cross-sectional view to represent properties/functions of elements of the semiconductor device 300.

FIG. 3 shows a semiconductor substrate 302 and one or more transition layers 304 over and on the semiconductor substrate 302. A channel layer 306 is over and on the uppermost transition layer 304. A barrier layer 308 is over and on the channel layer 306.

The semiconductor substrate 302 may be a bulk semiconductor substrate, a semiconductor-on-insulator (SOI) substrate, or any other appropriate substrate. For example, the semiconductor substrate 302 may be or include a bulk silicon wafer. The transition layer(s) 304 may include any number of layers of any materials that are configured to accommodate lattice mismatch between the semiconductor substrate 302 and the channel layer 306 (e.g., to reduce or minimize lattice defect generation and/or propagation in the channel layer 306). For example, the transition layer(s) 304 may have a gradient concentration of one or more elements in a direction normal to the upper surface of the semiconductor substrate 302.

The channel layer 306 is configured, possibly in conjunction with the barrier layer 308, to conduct and confine charge carriers (such as electrons) within two dimensions. In some examples, the channel layer 306 is configured to include a 2DEG in various examples. The 2DEG may be formed by energy band bending resulting from the barrier layer 308 being over and on the channel layer 306. In some examples, the channel layer 306 may be a portion of a semiconductor substrate (e.g., without transition layer(s), and/or the semiconductor substrate 302 with the transition layer(s) 304 and the channel layer 306 may be considered a semiconductor substrate. In some examples, the channel layer 306 includes a gallium nitride (GaN) layer and, in such examples, may be referred to as a GaN channel layer. In some examples, the material of the channel layer 306 is or includes an unintentionally doped material, such as a material doped by diffusion of dopants from another layer, or is or includes an intrinsic material. The barrier layer 308, in some examples, may be or include an aluminum gallium nitride (AlGaN) layer and, in such examples, may be referred to as an AlGaN barrier layer. More generally, in some examples, the channel layer 306 may be or include indium aluminum gallium nitride (InᵢAlⱼGa₁₋ᵢ₋ⱼN) (where 0≤i≤1, 0≤j≤1, and 0≤i+j≤1), and the barrier layer 308 may be or include indium aluminum gallium nitride (InₖAl_{f}Ga₁₋ₖ₋ₗN) (where 0≤k≤1, 0≤l≤1, and 0≤k+l≤1). Other materials may be implemented for the channel layer 306 and/or the barrier layer 308.

A gate layer 310 is over and on an upper surface of the barrier layer 308. In some examples, the gate layer 310 is or includes a semiconductor layer of a semiconductor material. Further, in some examples, the gate layer 310 is doped with a dopant. In some examples, the gate layer 310 is doped with a p-type dopant. In some examples, the gate layer 310 may be or include a gallium nitride (GaN) layer, or more generally, indium aluminum gallium nitride (InₘAlₙGa₁₋ₘ₋ₙN) (where 0≤m<1, 0≤n<1, and 0≤m+n≤1), and the dopant with which the gate layer 310 is doped is a p-type dopant, which may be or include magnesium (Mg), carbon (C), zinc (Zn), the like, or a combination thereof. In examples in which the gate layer 310 is gallium nitride (GaN) doped with a p-type dopant, the gate layer 310 may be referred to as a p-doped GaN (pGaN) layer. Further, in examples in which the gate layer 310 is gallium nitride (GaN) doped with a magnesium, the gate layer 310 may be referred to as a magnesium doped gallium nitride (GaN:Mg) layer. In some examples, a concentration of the dopant in the gate layer 310, which is electrically activated, is equal to or greater than 1×10¹⁷ cm⁻³. In some examples, the concentration is equal to or greater than 1×10¹⁸ cm⁻³. Other materials, dopants, and/or concentrations may be implemented in other examples.

The semiconductor device 300 includes a source region S, a channel region C, a drain region D, and a gate structure G. The gate structure G includes the gate layer 310. The channel region C is in the channel layer 306 underlying the gate structure G. The channel region C is laterally between the drain region D and the source region S, which are also in the channel layer 306.

A first dielectric layer 320 is over and on the barrier layer 308 and the gate layer 310. The first dielectric layer 320 is over and on respective upper surfaces of the barrier layer 308 and the gate layer 310 and along sidewall surfaces of the gate layer 310. The first dielectric layer 320 may include multiple dielectric layers of a same dielectric material or different dielectric materials. For example, the first dielectric layer 320 may include a silicon oxide-based material, such as a phosphosilicate glass (PSG), and may further include one or more etch stop layers, such as silicon nitride (SiN) or the like.

A gate electrical contact 322 extends through the first dielectric layer 320 and contacts the gate layer 310. Lateral portions of the gate electrical contact 322 may be over and on an upper surface of the first dielectric layer 320. The gate electrical contact 322 includes a first metal portion and a second metal portion. In the illustrated example, the first metal portion includes a first metal layer 324, and the second metal portion includes a second metal layer 326. The first metal layer 324 generally is conformal on an upper surface of the gate layer 310, sidewall surfaces of an opening through the first dielectric layer 320, and the upper surface of the first dielectric layer 320. The first metal layer 324 contacts a first surface area of the gate layer 310. The second metal layer 326 is generally conformal on the first metal layer 324 and extends through an opening through the first metal layer 324 (which is further through the opening through the first dielectric layer 320) to contact the gate layer 310. The second metal layer 326 contacts a second surface area of the gate layer 310. In some examples, the first surface area (e.g., where the first metal layer 324 contacts the gate layer 310) is larger than the second surface area (e.g., where the second metal layer 326 contacts the gate layer 310). In some examples, the first surface area may be at least 10 times larger than the second surface area, such as in a range from 10 to 100 times larger than the second surface area.

The first metal portion of the gate electrical contact 322 (e.g., the first metal layer 324) forms a high energy barrier height junction 334, e.g., illustrated by a Schottky diode symbol, with a first semiconductor portion of the gate layer 310 where the first metal portion contacts the first semiconductor portion of the gate layer 310. The second metal portion of the gate electrical contact 322 (e.g., the second metal layer 326) forms a low energy barrier height junction 336, e.g., illustrated by a resistance (e.g., an ohmic junction), with a second semiconductor portion of the gate layer 310 where the second metal portion contacts the second semiconductor portion of the gate layer 310. In some examples, the first metal portion of the gate electrical contact 322 (e.g., the first metal layer 324) has a work function that is greater than a work function of the second metal portion of the gate electrical contact 322 (e.g., the second metal layer 326). In some examples, the work function of the first metal portion of the gate electrical contact 322 is equal to or greater than 4.6 electron volt (eV), and the work function of the second metal portion of the gate electrical contact 322 is less than 4.6 eV. In some examples, the high energy barrier height junction 334 has an energy barrier height that is greater than an energy barrier height of the low energy barrier height junction 336. In some examples, the energy barrier height of the high energy barrier height junction 334 is equal to or greater than 1.7 eV, and the energy barrier height of the low energy barrier height junction 336 is less than 1.7 eV. In some examples, the high energy barrier height junction 334 may be a high energy barrier height Schottky junction, and the low energy barrier height junction 336 may be an ohmic junction (e.g., having an energy barrier height of about 0 eV) or may be a low energy barrier height Schottky junction. Within the gate electrical contact 322, the first metal portion (e.g., the first metal layer 324) forms an ohmic junction with the second metal portion (e.g., the second metal layer 326).

The first metal portion (e.g., the first metal layer 324) and the second metal portion (e.g., the second metal layer 326) may be or include different metals. An energy barrier height of a junction between a given metal and a semiconductor material can be a function of the materials of the metal and semiconductor material and any doping of the semiconductor material. To obtain the unequal energy barrier heights of the junctions 334, 336 as described above, in the illustrated example, the first metal layer 324 is or includes a different metal from the second metal layer 326. In the illustrated example, the first semiconductor portion of the gate layer 310 is a same semiconductor material and is doped (e.g., with a p-type dopant) the same as the second semiconductor portion of the gate layer 310. As examples, the gate layer 310 may be a magnesium doped gallium nitride (GaN:Mg) layer with magnesium (Mg) doped at an activated concentration of 2×10¹⁸ cm⁻³; the first metal layer 324 may be titanium (Ti), titanium tungsten (TiW), titanium nitride (TiN), nickel (Ni), platinum (Pt), tantalum nitride (TaN), copper (Cu), tungsten (W), or alloys thereof; and the second metal layer 326 may be gold (Au), aluminum (Al), or alloys thereof, which alloys may include titanium tungsten aluminum (TiWAl) and titanium aluminum nitride (TiAlN), each with an increased percentage of aluminum. In some examples, the first and second metal portions have different metal materials, where the metal materials can include any of the metal materials described above, such as titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), and titanium aluminum nitride (TiAlN).

In some examples, the first and second metal portions can also have a same metal, a same metal material, or a same metal alloy composition. The same metal/metal material/metal alloy can include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), and titanium aluminum nitride (TiAlN). The first and second metal portions can be processed with different process conditions (e.g., different anneal conditions, different deposition/etch conditions, etc.) to create junctions of different barrier heights.

FIG. 3 also shows a reference plane 340 in an x-y plane. The reference plane 340 intersects the gate electrical contact 322. A pattern of the first metal portion and the second metal portion of gate electrical contact 322 is illustrated by subsequent three-dimensional (3D) figures that show the pattern at the reference plane 340.

A source electrical contact 342 extends through the first dielectric layer 320 and contacts the channel layer 306 at the source region S, and a drain electrical contact 344 extends through the first dielectric layer 320 and contacts the channel layer 306 at the drain region D. The source electrical contact 342 and the drain electrical contact 344 are electrically coupled to the source region S and the drain region D, respectively, in the channel layer 306. The gate structure G (including the gate layer 310) is laterally between the source electrical contact 342 and the drain electrical contact 344. Metal lines 352, 354 in a first metal layer are over and on the electrical contacts 342, 344, respectively, and an upper surface of the first dielectric layer 320. The electrical contacts 342, 344 may each include one or more metal-barrier and/or adhesion layers (e.g., titanium nitride (TiN), tantalum nitride (TaN), the like, or a combination thereof) conformally in a respective opening through the first dielectric layer 320, and a fill metal (e.g., aluminum (Al), copper (Cu), tungsten (W), the like, or a combination thereof) over and/or on the metal-barrier and/or adhesion layer(s). The metal lines 352, 354 may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

A second dielectric layer 360 is over and on the first dielectric layer 320, the gate electrical contact 322, and the metal lines 352, 354. The second dielectric layer 360 may be a single dielectric layer or may include multiple dielectric layers of a same dielectric material or different dielectric materials. For example, the second dielectric layer 360 may include a silicon oxide-based material, such as a PSG, and may further include one or more etch stop layers, such as silicon nitride (SiN) or the like.

Metal vias 362, 364 extend through the second dielectric layer 360 and contact the metal lines 352, 354, respectively. Metal lines 372, 374 in a second metal layer are over and on the metal vias 362, 364, respectively, and an upper surface of the second dielectric layer 360. The metal vias 362, 364 may each include one or more metal-barrier and/or adhesion layers (e.g., titanium nitride (TiN), tantalum nitride (TaN), the like, or a combination thereof) conformally in a respective opening through the second dielectric layer 360, and a fill metal (e.g., tungsten (W), copper (Cu), aluminum (Al), the like, or a combination thereof) over and/or on the metal-barrier and/or adhesion layer(s). The metal lines 372, 374 may include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

Additional dielectric layers and metal layers may be formed over and on the second dielectric layer 360. The first dielectric layer 320, second dielectric layer 360, additional dielectric layers, first metal layer, second metal layer, and additional metal layers may form an interconnect structure. Metal lines in neighboring metal layers may be electrically coupled by metal vias.

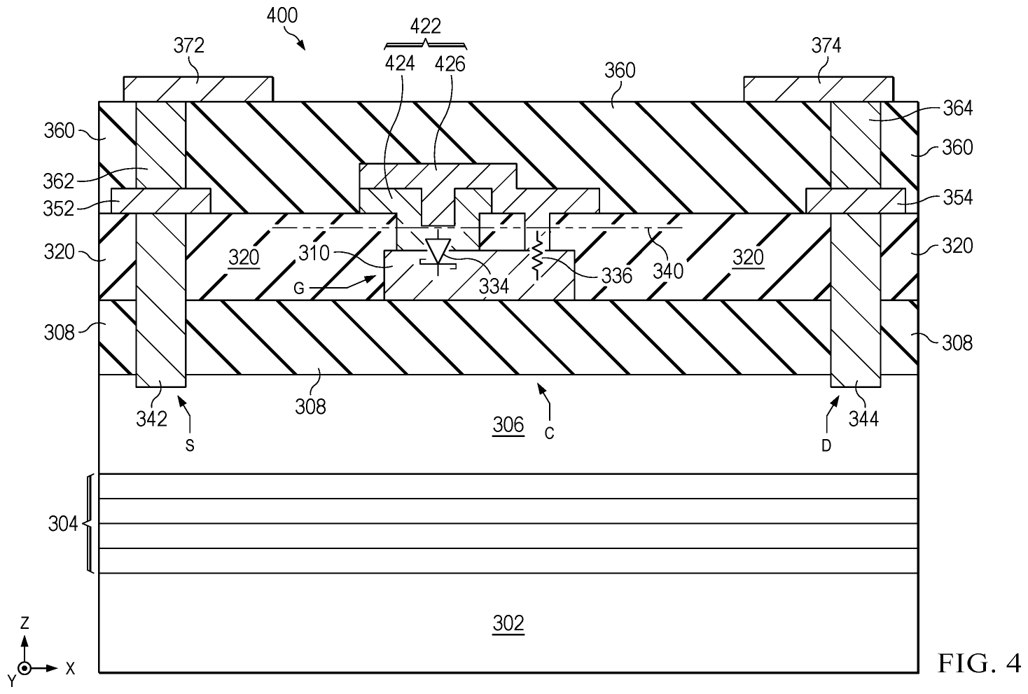

FIG. 4 illustrates a cross-sectional view of a semiconductor device 400 according to some examples. The semiconductor device 400, in this example, is or includes a HEMT. Further, the semiconductor device 400 may be or include an enhancement mode HEMT. Other examples may be or include other types of devices.

The semiconductor device 400 of FIG. 4 includes at least some components of the semiconductor device 300 of FIG. 3 and a gate electrical contact 422. The gate electrical contact 422 extends through the first dielectric layer 320 and contacts the gate layer 310. Lateral portions of the gate electrical contact 422 may be over and on an upper surface of the first dielectric layer 320. The gate electrical contact 422 includes a first metal portion and a second metal portion. In the illustrated example, the first metal portion includes a first metal layer 424, and the second metal portion includes a second metal layer 426. The first metal layer 424 can be conformal on an upper surface of the gate layer 310, sidewall surfaces of a first opening through the first dielectric layer 320, and the upper surface of the first dielectric layer 320. The first metal layer 424 contacts a first surface area of the upper surface of the gate layer 310 through the first opening. The second metal layer 426 is on the upper surface of the gate layer 310, sidewall surfaces of a second opening through the first dielectric layer 320, the upper surface of the first dielectric layer 320, and the first metal layer 424. The first opening through the first dielectric layer 320 is separated from the second opening through the first dielectric layer 320. The second metal layer 426 contacts a second surface area of the upper surface of the gate layer 310 through the second opening. As illustrated by methods of fabrication described subsequently, etching an opening through the first metal layer 424 (e.g., in which the second metal layer 426 is deposited) may be avoided in forming the gate electrical contact 422, which may reduce an impact at the interface between the second metal layer 426 and the gate layer 310.

Other aspects of the first metal layer 424 and the second metal layer 426 are like the first metal layer 324 and the second metal layer 326, respectively, of FIG. 1. Specifically, description relating to the surface areas of the gate layer 310 that the metal layers 324, 326 contact, the junctions 334, 336 and energy barrier heights that the metal layers 324, 326 form with the gate layer 310, and materials of the metal layers 324, 326 likewise apply to the first metal layer 424 and the second metal layer 426 of FIG. 4.

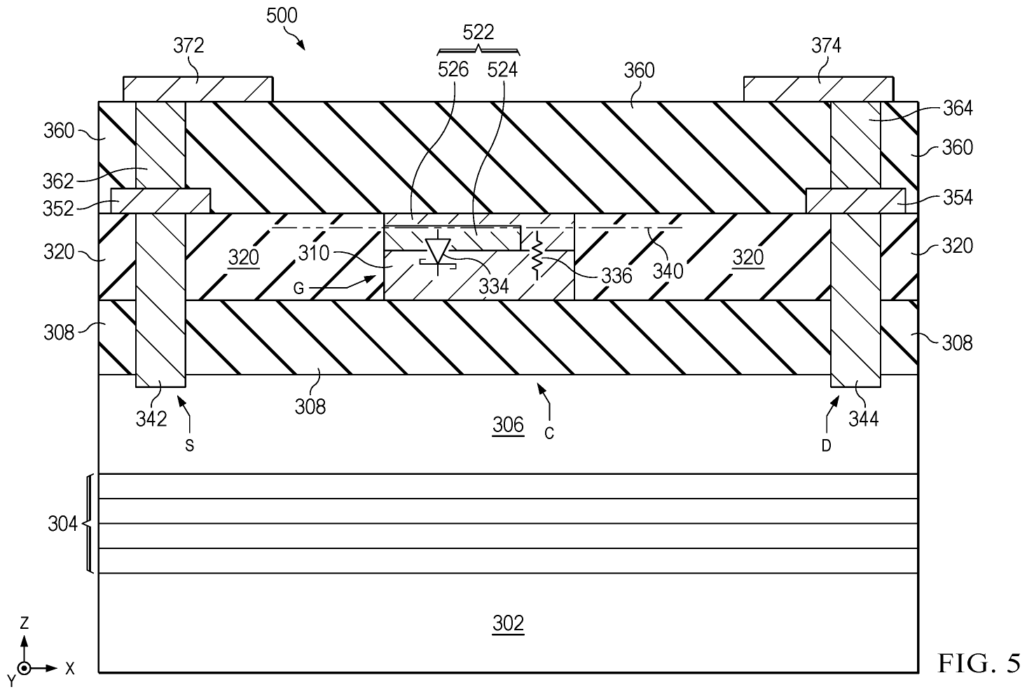

FIG. 5 illustrates a cross-sectional view of a semiconductor device 500 according to some examples. The semiconductor device 500, in this example, is or includes a HEMT. Further, the semiconductor device 500 may be or include an enhancement mode HEMT. Other examples may be or include other types of devices.

The semiconductor device 500 of FIG. 5 includes at least some of the components of the semiconductor device 300 of FIG. 3 and a gate electrical contact 522. The gate electrical contact 522 extends through the first dielectric layer 320 and contacts the gate layer 310. The gate electrical contact 522 includes a first metal portion and a second metal portion. In the illustrated example, the first metal portion includes a first metal layer 524, and the second metal portion includes a second metal layer 526. The first metal layer 524 can be on an upper surface of the gate layer 310 in an opening through the first dielectric layer 320. The first metal layer 524 contacts a first surface area of the upper surface of the gate layer 310. The second metal layer 526 can be on the first metal layer 524 and can be on the upper surface of the gate layer 310 in the opening through the first dielectric layer 320. The second metal layer 526 contacts a second surface area of the upper surface of the gate layer 310. As illustrated by a method of fabrication described subsequently, the gate electrical contact 522 may be formed by a self-aligned process for forming the gate electrical contact 522 and the gate layer 310. The self-aligned process may help prevent misalignment of the gate electrical contact from the gate layer 310.

Other aspects of the first metal layer 524 and the second metal layer 526 are like the first metal layer 324 and the second metal layer 326, respectively, of FIG. 1. Specifically, description relating to the surface areas of the gate layer 310 that the metal layers 324, 326 contact, the junctions 334, 336 and energy barrier heights that the metal layers 324, 326 form with the gate layer 310, and materials of the metal layers 324, 326 likewise apply to the first metal layer 524 and the second metal layer 526 of FIG. 5.

FIGS. 6, 7, 8, and 9 are perspective views of respective semiconductor devices 600, 700, 800, 900 according to some examples. The semiconductor devices 600, 700, 800, 900 may be implementations of any of the semiconductor devices 300, 400, 500 of FIGS. 3, 4, and 5. Each of the semiconductor devices 600, 700, 800, 900, as illustrated, includes the channel layer 306, the barrier layer 308, the gate layer 310, and the drain electrical contact 344. The semiconductor devices 600, 700, 800, 900 include respective gate electrical contacts (which may correspond to any of the gate electrical contacts of FIGS. 3, 4, and 5) having an illustrated upper surface that corresponds to the reference plane 340 described above. The gate electrical contacts may actually have different upper surfaces. A gate electrical contact in FIGS. 6, 7, 8, and 9 includes a first metal layer that corresponds to a first metal layer 324, 424, 524 and includes a second metal layer that corresponds to a second metal layer 326, 426, 526, respectively. A gate electrical contact in FIGS. 6, 7, 8, and 9 forms the junctions with a gate layer 310 as described above. Further, the semiconductor devices 600, 700, 900 of FIGS. 6, 7, and 9 also include the source electrical contact 342.

Referring to FIG. 6, a gate electrical contact includes a first metal layer 624 and a second metal layer 626. The illustration of FIG. 6 shows the gate layer 310 extending in a channel width direction (e.g., a y-direction) from a lateral boundary (e.g., along an x-direction) of an active area to another lateral boundary (e.g., along another x-direction) of the active area. Portions of the second metal layer 626 that contact the upper surface of the gate layer 310 are at sidewalls of the gate layer 310 where the sidewalls intersect respective lateral boundaries of the active area. These intersection points are illustrated as corners of the gate layer 310, although it is noted that the gate layer 310 may extend beyond lateral boundaries of the active area. Another portion of the second metal layer 626 that contacts the upper surface of the gate layer 310 is centrally located in the gate layer 310 with respect to the lateral boundaries of the active area that the gate layer 310 intersects. A similar pattern of the portions of the second metal layer 626 that contact the gate layer 310 may be repeated on the gate layer 310.

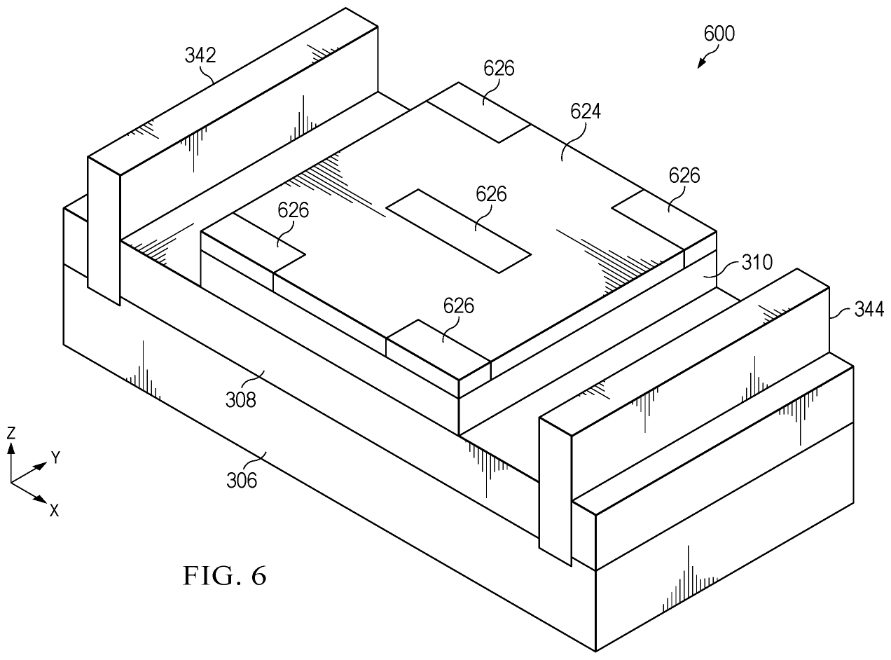

Referring to FIG. 7, a gate electrical contact includes a first metal layer 724 and a second metal layer 726. The illustration of FIG. 7 shows the gate layer 310 extending in a channel width direction (e.g., a y-direction) from a lateral boundary (e.g., along an x-direction) of an active area to another lateral boundary (e.g., along another x-direction) of the active area. Portions of the second metal layer 726 that contact the upper surface of the gate layer 310 extend longitudinally along and across the upper surface of the gate layer 310 in a channel length direction (e.g., an x-direction). Two portions of the second metal layer 726 are shown. Other examples may include more portions of the second metal layer 726 that contact the upper surface of the gate layer 310. Having the second metal layer 626, 726 of FIGS. 6 and 7 interspersed throughout the gate layer 310 may facilitate biasing the gate layer 310 to a same potential throughout the gate layer 310. FIGS. 6 and 7 show different layouts of the portions of the second metal layer 626, 726 that may trade off gate current, ohmic delay, and other considerations. Layout dependent tradeoffs may be balanced for drain saturation current (I_{DSAT}) and gate overdrive voltage (V_{GT}) increase versus gate-to-channel resistance (R_{GC}) delay and gate current (I_{G}) increase.

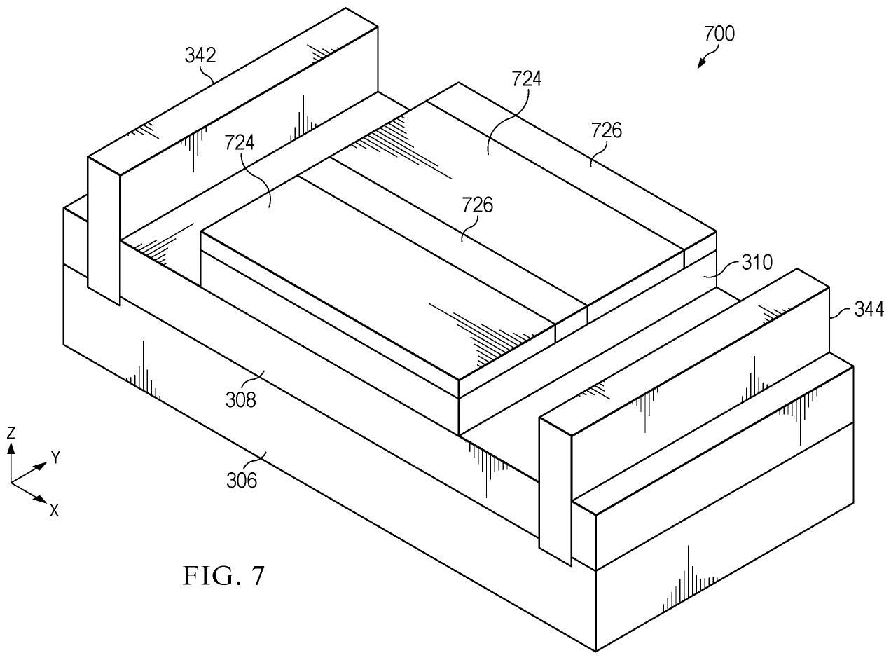

Referring to FIG. 8, a gate electrical contact includes a first metal layer 824 and a second metal layer 826. The illustration of FIG. 8 shows the gate layer 310 extending in a channel width direction (e.g., a y-direction) from a lateral boundary (e.g., along an x-direction) of an active area to another lateral boundary (e.g., along another x-direction) of the active area. Portions of the second metal layer 826 that contact the upper surface of the gate layer 310 are at a sidewall of the gate layer 310 proximate a source electrical contact 842 where the sidewalls intersect respective lateral boundaries of the active area. These intersection points are illustrated as corners of the gate layer 310, although it is noted that the gate layer may extend beyond lateral boundaries of the active area. Portions of the second metal layer 826 that contact the gate layer 310 may be repeated on the gate layer 310 in a similar manner.

A side of the source electrical contact 842 proximate the gate layer 310 is notched 846 in a channel length direction (e.g., in an x-direction) corresponding to where the second metal layer 826 contacts the upper surface of the gate layer 310. A first dimension 852 (e.g., in an x-direction) is between a sidewall surface of the source electrical contact 842 (outside of any notch 846) and a sidewall surface of the gate layer 310 at a mid-point between the portions of the second metal layer 826 that contact the upper surface of the gate layer 310. A second dimension 854 (e.g., in an x-direction) is between a sidewall surface of the source electrical contact 842 at a respective notch 846 and the sidewall surface of the gate layer 310 where a respective portion of the second metal layer 826 contacts the upper surface of the gate layer 310. The second dimension 854 is greater than the first dimension 852. Hence, the side of the source electrical contact 842 correlates with the placement of the second metal layer 826 contacting the gate layer 310 such the source electrical contact 842 maintains a greater distance from portions of the second metal layer 826 than the first metal layer 824. Such correlation may result in a lower gate-to-source current in regions proximate the portions of the second metal layer 826. Additionally, the gate electrical contact may result in less de-biasing. By increasing a gate-to-source length (L_{GS}), the voltage drop (e.g., the current times resistance voltage drop) is increased in the gate-to-source length, and the effective gate overdrive voltage (V_{GT}) is reduced, which reduces the gate current (I_{G}). De-biasing may be an effective reduction in an internal gate-to-source voltage due to an increase in voltage drop in a source electrical contact and/or access region (e.g., a region of the barrier layer 308 and/or channel layer 306 laterally between the source electrical contact and gate layer 310). The source electrical contact may dominate (e.g., relative to the drain electrical contact) for gate overdrive voltage (V_{GT}) and gate-to-source current (I_{GS}). Gate-to-drain current (I_{GD}) may be low as drain electrical contact may be relatively far from the gate layer 310. Further, the gate electrical contact and source electrical contact 842 may result in less active area penalty.

Referring to FIG. 9, a gate electrical contact includes a first metal layer 924 and a second metal layer 926. The illustration of FIG. 9 shows the gate layer 310 extending in a channel width direction (e.g., a y-direction) beyond a lateral boundary 902 (e.g., along an x-direction) of an active area. The first metal layer 924 contacts the upper surface of the gate layer 310 within the boundary of the active area, and the second metal layer 926 contacts the upper surface of the gate layer 310 outside of the lateral boundary 902 of the active area. Having the second metal layer 926 contact the upper surface of the gate layer 310 outside of the active area may increase a distance between (i) the second metal layer 926 and (ii) the source electrical contact 342 and/or the drain electrical contact 344, which may reduce gate-to-source and gate-to-drain leakage.

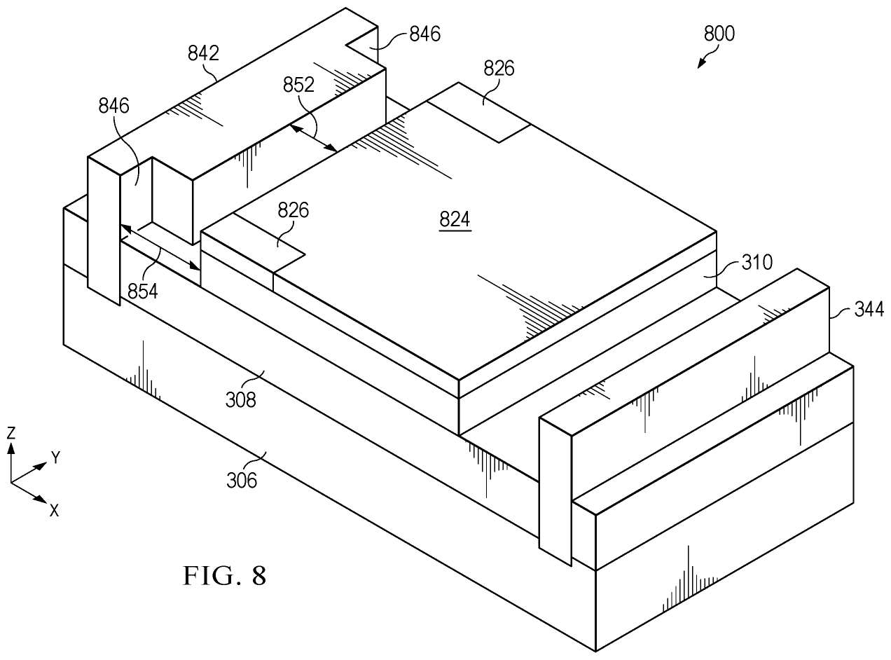

FIG. 10 is a layout view of a semiconductor device 1000 according to some examples. The semiconductor device 1000 of FIG. 10 further illustrates some aspects of the semiconductor device 900 of FIG. 9. The semiconductor device 1000 may be referred to as a multi-finger device in which various components are electrically coupled together to form the semiconductor device 1000. FIG. 10 illustrates active areas 1002, 1004. An isolation region, such as a shallow trench isolation (STI) region, may define one or more boundaries of the active areas 1002, 1004. For example, isolation region(s) may be outside of the active areas 1002, 1004, where the active areas 1002, 1004 include the channel layer 306 and barrier layer 308 between the isolation region(s).

The semiconductor device 1000 includes multiple gate layers 310 across the active areas 1002, 1004 and multiple source electrical contacts 342 and multiple drain electrical contacts 344 contacting the active areas 1002, 1004. The source electrical contacts 342 are electrically coupled together (not illustrated), and the drain electrical contacts 344 are electrically coupled together (not illustrated). The gate electrical contact includes a first metal layer 1024 and a second metal layer 1026. The first metal layer 1024 is on the respective gate layers 310 within the boundaries of a respective active area 1002, 1004. The second metal layer 1026 is on the gate layers 310 between and outside of the active areas 1002, 1004. The second metal layer 1026 electrically couples the gate layers 310 together.

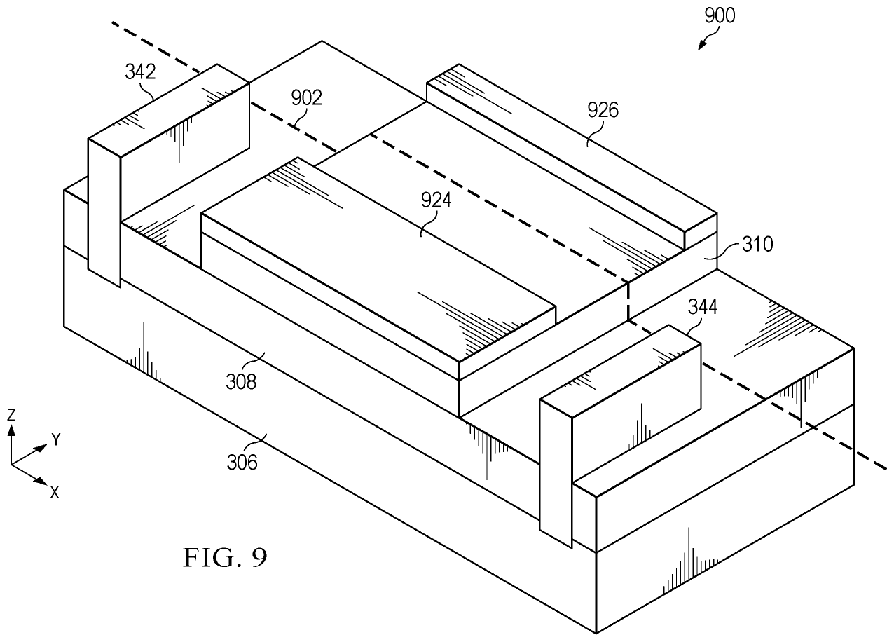

FIG. 11 illustrates a cross-sectional view of a semiconductor device 1100 according to some examples. The semiconductor device 1100, in this example, is or includes a HEMT. Further, the semiconductor device 1100 may be or include an enhancement mode HEMT. Other examples may be or include other types of devices.

The semiconductor device 1100 of FIG. 11 includes at least some components of the semiconductor device 300 of FIG. 3 and a gate electrical contact 1122. The gate electrical contact 1122 extends through the first dielectric layer 320 and contacts the gate layer 310. Lateral portions of the gate electrical contact 1122 may be over and on an upper surface of the first dielectric layer 320. The gate electrical contact 1122 includes a first metal portion and a second metal portion. In the illustrated example, the first metal portion includes a first metal layer 1124, and the second metal portion includes a second metal layer 1126. The first metal layer 1124 can be conformal on an upper surface of the gate layer 310, sidewall surfaces of a first opening through the first dielectric layer 320, and the upper surface of the first dielectric layer 320. The first metal layer 1124 contacts a first surface area of the upper surface of the gate layer 310. The second metal layer 1126 can be conformal on the first metal layer 1124 and extends through an opening through the first metal layer 1124 (which is through a second opening through the first dielectric layer 320) to contact a sidewall surface of the gate layer 310. The second metal layer 1126 contacts a second surface area of the sidewall surface of the gate layer 310.

Other aspects of the first metal layer 1124 and the second metal layer 1126 are like the first metal layer 324 and the second metal layer 326, respectively, of FIG. 1. Specifically, description relating to the surface areas of the gate layer 310 that the metal layers 324, 326 contact, the junctions 334, 336 and energy barrier heights that the metal layers 324, 326 form with the gate layer 310, and materials of the metal layers 324, 326 likewise apply to the first metal layer 1124 and the second metal layer 1126 of FIG. 11.

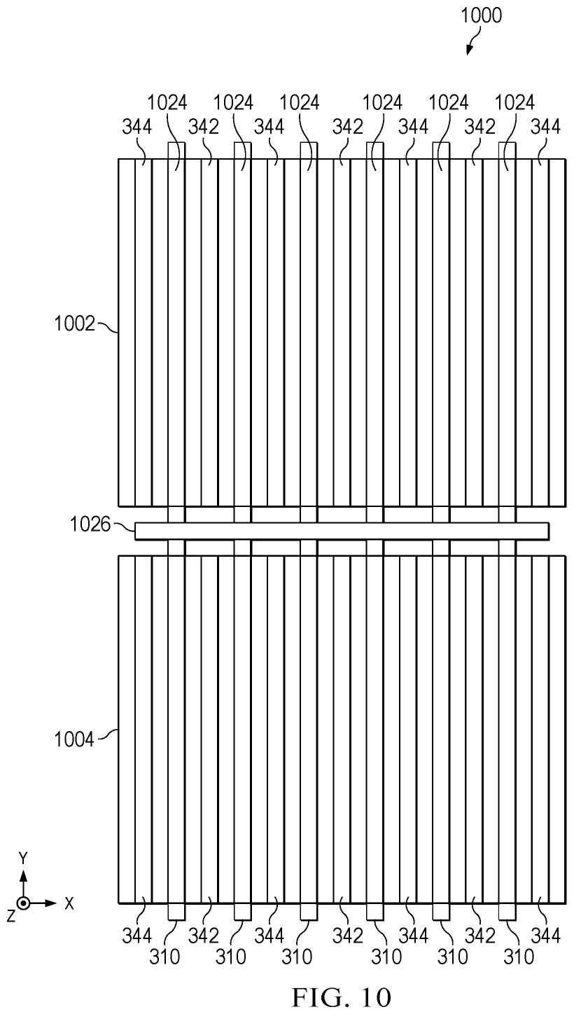

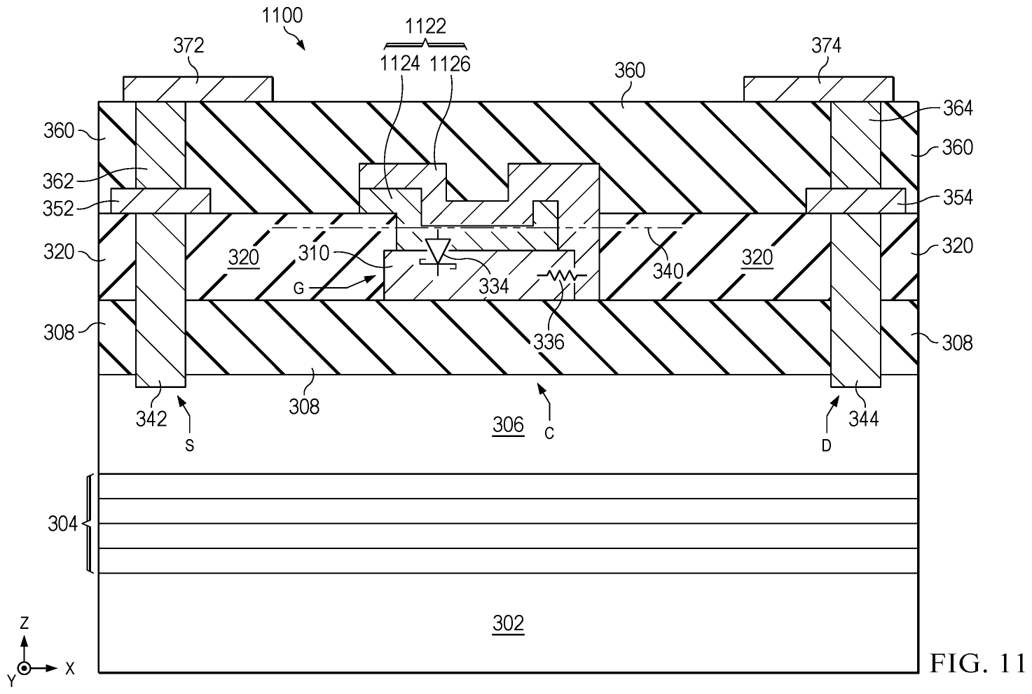

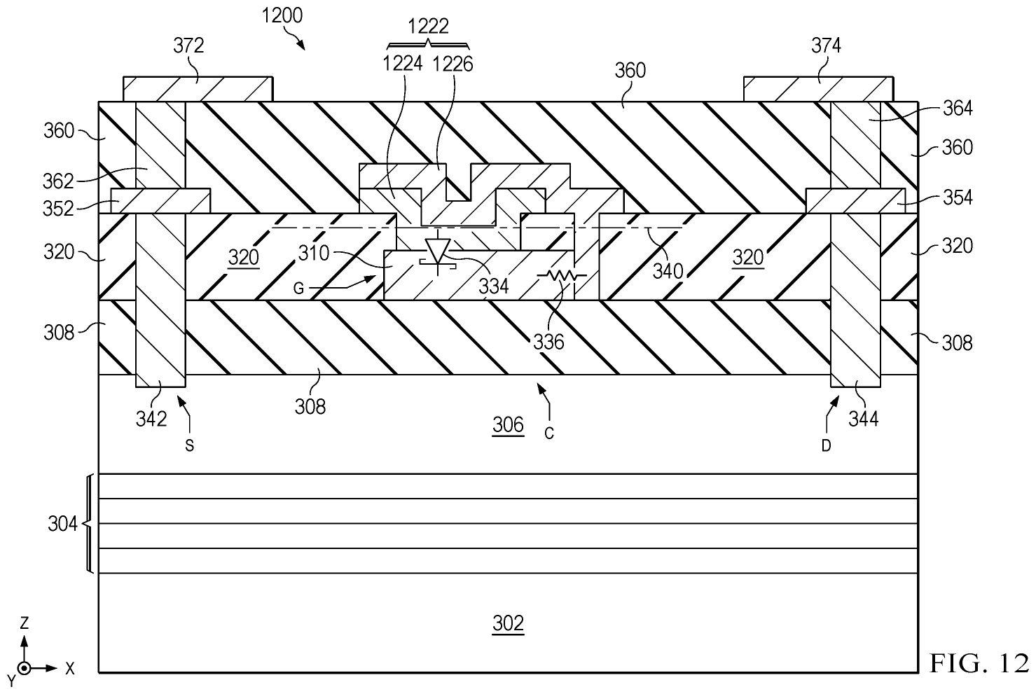

FIG. 12 illustrates a cross-sectional view of a semiconductor device 1200 according to some examples. The semiconductor device 1200, in this example, is or includes a HEMT. Further, the semiconductor device 1200 may be or include an enhancement mode HEMT. Other examples may be or include other types of devices.

The semiconductor device 1200 of FIG. 12 includes at least some components of the semiconductor device 300 of FIG. 3 and a gate electrical contact 1222. The gate electrical contact 1222 extends through the first dielectric layer 320 and contacts the gate layer 310. Lateral portions of the gate electrical contact 1222 may be over and on an upper surface of the first dielectric layer 320. The gate electrical contact 1222 includes a first metal portion and a second metal portion. In the illustrated example, the first metal portion includes a first metal layer 1224, and the second metal portion includes a second metal layer 1226. The first metal layer 1224 can be conformal on an upper surface of the gate layer 310, sidewall surfaces of a first opening through the first dielectric layer 320, and the upper surface of the first dielectric layer 320. The first metal layer 1224 contacts a first surface area of the upper surface of the gate layer 310. The second metal layer 1226 is on a sidewall surface of the gate layer 310, sidewall surfaces of a second opening through the first dielectric layer 320, the upper surface of the first dielectric layer 320, and the first metal layer 1224. The first opening through the first dielectric layer 320 is separated from the second opening through the first dielectric layer 320. The second metal layer 1226 contacts a second surface area of the sidewall surface of the gate layer 310.

Other aspects of the first metal layer 1224 and the second metal layer 1226 are like the first metal layer 324 and the second metal layer 326, respectively, of FIG. 1. Specifically, description relating to the surface areas of the gate layer 310 that the metal layers 324, 326 contact, the junctions 334, 336 and energy barrier heights that the metal layers 324, 326 form with the gate layer 310, and materials of the metal layers 324, 326 likewise apply to the first metal layer 1224 and the second metal layer 1226 of FIG. 12.

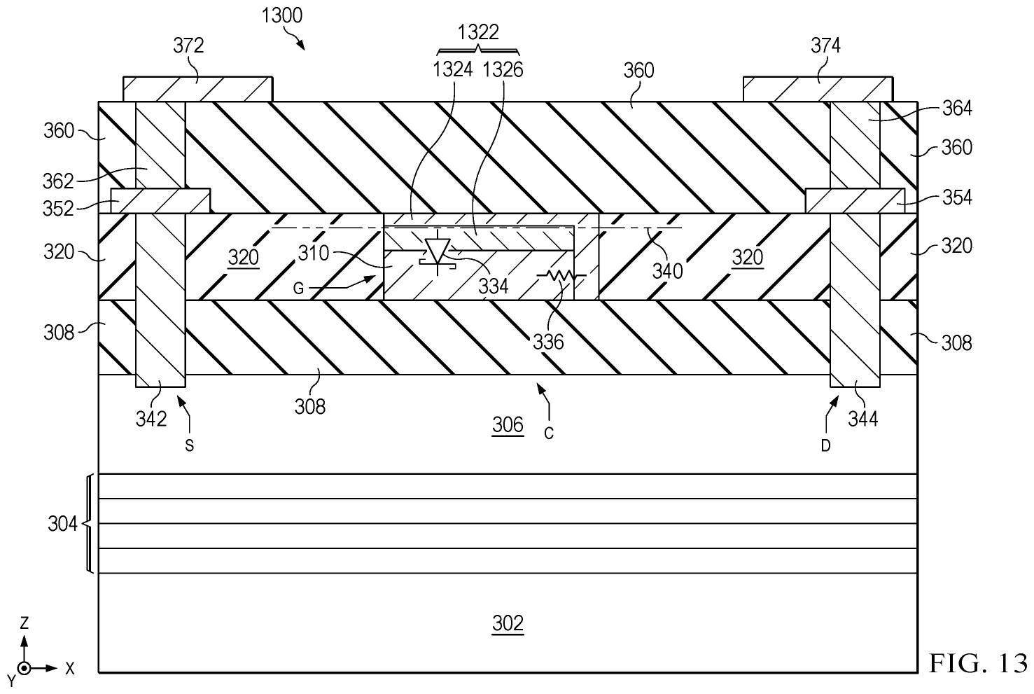

FIG. 13 illustrates a cross-sectional view of a semiconductor device 1300 according to some examples. The semiconductor device 1300, in this example, is or includes a HEMT. Further, the semiconductor device 1300 may be or include an enhancement mode HEMT. Other examples may be or include other types of devices.

The semiconductor device 1300 of FIG. 13 includes at least some components of the semiconductor device 300 of FIG. 3 and a gate electrical contact 1322. The gate electrical contact 1322 extends through the first dielectric layer 320 and contacts the gate layer 310. The gate electrical contact 1322 includes a first metal portion and a second metal portion. In the illustrated example, the first metal portion includes a first metal layer 1324, and the second metal portion includes a second metal layer 1326. The first metal layer 1324 can be on an upper surface of the gate layer 310 in an opening through the first dielectric layer 320. The first metal layer 1324 contacts a first surface area of the upper surface of the gate layer 310. The second metal layer 1326 can be on the first metal layer 1324 and is on a sidewall surface of the gate layer 310 in the opening through the first dielectric layer 320. The second metal layer 1326 contacts a second surface area of the sidewall surface of the gate layer 310.

Other aspects of the first metal layer 1324 and the second metal layer 1326 are like the first metal layer 324 and the second metal layer 326, respectively, of FIG. 1. Specifically, description relating to the surface areas of the gate layer 310 that the metal layers 324, 326 contact, the junctions 334, 336 and energy barrier heights that the metal layers 324, 326 form with the gate layer 310, and materials of the metal layers 324, 326 likewise apply to the first metal layer 1324 and the second metal layer 1326 of FIG. 13.

FIGS. 14 and 15 are perspective views of respective semiconductor devices 1400, 1500 according to some examples. The semiconductor devices 1400, 1500 may be implementations of any of the semiconductor devices 1100, 1200, 1300 of FIGS. 11, 12, and 13. Each of the semiconductor devices 1400, 1500, as illustrated, includes the channel layer 306, the barrier layer 308, the gate layer 310, and the drain electrical contact 344. The semiconductor devices 1400, 1500 include respective gate electrical contacts (which may correspond to any of the gate electrical contacts of FIGS. 11, 12, and 13) having an illustrated upper surface that corresponds to the reference plane 340 described above. The gate electrical contacts may actually have different upper surfaces. A gate electrical contact in FIGS. 14 and 15 includes a first metal layer that corresponds to a first metal layer 1124, 1224, 1324 and includes a second metal layer that corresponds to a second metal layer 1126, 1226, 1326, respectively. A gate electrical contact in FIGS. 14 and 15 forms the junctions with a gate layer 310 as described above. Further, the semiconductor device 1400 of FIG. 14 also includes the source electrical contact 342.

Referring to FIG. 14, a gate electrical contact includes a first metal layer 1424 and a second metal layer 1426. The illustration of FIG. 14 shows the gate layer 310 extending in a channel width direction (e.g., a y-direction) beyond a lateral boundary 1402 (e.g., along an x-direction) of an active area. The first metal layer 1424 contacts the upper surface of the gate layer 310 at least within the boundary of the active area, and the second metal layer 1426 contacts a sidewall surface of the gate layer 310 outside of the lateral boundary 1402 of the active area. Having the second metal layer 1426 contact the sidewall surface of the gate layer 310 outside of the active area may increase a distance between (i) the second metal layer 1426 and (ii) the source electrical contact 342 and/or the drain electrical contact 344, which may reduce gate-to-source and gate-to-drain leakage.

Referring to FIG. 15, a gate electrical contact includes a first metal layer 1524 and a second metal layer 1526. The illustration of FIG. 15 shows the gate layer 310 extending in a channel width direction (e.g., a y-direction) from a lateral boundary (e.g., along an x-direction) of an active area to another lateral boundary (e.g., along another x-direction) of the active area. Portions of the second metal layer 1526 contact a sidewall surface of the gate layer 310 proximate a source electrical contact 1542 and where the sidewall intersect respective lateral boundaries of the active area. These intersection points are illustrated as at corners of the gate layer 310, although it is noted that the gate layer may extend beyond lateral boundaries of the active area. Portions of the second metal layer 1526 that contact the gate layer 310 may be repeated along the sidewall surface of the gate layer 310 in a similar manner.

A side of the source electrical contact 1542 is notched 1546 in a channel length direction (e.g., in an x-direction) corresponding to where the second metal layer 1526 contacts the sidewall surface of the gate layer 310. A first dimension 1552 (e.g., in an x-direction) is between a sidewall surface of the source electrical contact 1542 (outside of any notch 1546) and a sidewall surface of the gate layer 310 at a mid-point between the portions of the second metal layer 1526 that contact the sidewall surface of the gate layer 310. A second dimension 1554 (e.g., in an x-direction) is between a sidewall surface of the source electrical contact 1542 at a respective notch 846 and a proximate sidewall surface of a respective portion of the second metal layer 1526 that contacts the sidewall surface of the gate layer 310. The second dimension 1554 is greater than the first dimension 1552. Hence, the side of the source electrical contact 1542 correlates with the placement of the second metal layer 1526 contacting the gate layer 310 such the source electrical contact 1542 maintains a greater distance from portions of the second metal layer 1526 than the first metal layer 1524. Such correlation may result in a lower gate-to-source current in regions proximate the portions of the second metal layer 1526. Additionally, the gate electrical contact may result in less de-biasing of the gate current (I_{G}). By increasing a gate-to-source length (L_{GS}), the voltage drop (e.g., the current times resistance voltage drop) is increased in the gate-to-source length, and the effective gate overdrive voltage (V_{GT}) is reduced, which reduces the gate current (I_{G}). Further, by having the second metal layer 1526 along a sidewall surface, any area of an etched opening that may intersect the sidewall surface of the gate layer 310 may permit forming the second metal layer 1526 along the sidewall surface, and hence, photolithography alignment concerns may be reduced.

FIG. 16 illustrates a cross-sectional view of a semiconductor device 1600 according to some examples. The semiconductor device 1600, in this example, is or includes a HEMT. Further, the semiconductor device 1600 may be or include an enhancement mode HEMT. Other examples may be or include other types of devices.

The semiconductor device 1600 of FIG. 16 includes at least some component of the semiconductor device 300 of FIG. 3 and a gate electrical contact 1622. The gate electrical contact 1622 extends through the first dielectric layer 320 and contacts the gate layer 310. Lateral portions of the gate electrical contact 1622 may be over and on an upper surface of the first dielectric layer 320. The gate electrical contact 1622 includes a first metal portion and a second metal portion. In the illustrated example, the gate electrical contact 1622 is a metal layer, where the first metal portion includes a first portion of the metal layer, and the second metal portion includes a second portion of the metal layer. The metal layer of the gate electrical contact 1622 is on an upper surface and sidewall surface of the gate layer 310, sidewall surfaces of an opening through the first dielectric layer 320, and the upper surface of the first dielectric layer 320. The first portion of the metal layer contacts a first surface area of the upper surface of the gate layer 310, and the second portion of the metal layer contacts a second surface area of the sidewall surface of the gate layer 310. In some examples, the first surface area (e.g., where the metal layer contacts the upper surface of the gate layer 310) is larger than the second surface area (e.g., where the metal layer contacts the sidewall surface of the gate layer 310). For example, the first surface area may be at least 10 times larger than the second surface area, such as in a range from 10 to 100 times larger than the second surface area.

The first metal portion of the gate electrical contact 1622 (e.g., the portion of the metal layer contacting the upper surface of gate layer 310) forms a high energy barrier height junction 334 with a first semiconductor portion of the gate layer 310 where the first metal portion contacts the first semiconductor portion of the gate layer 310. The second metal portion of the gate electrical contact 1622 (e.g., the portion of the metal layer contacting the sidewall surface of gate layer 310) forms a low energy barrier height junction 336 with a second semiconductor portion of the gate layer 310 where the second metal portion contacts the second semiconductor portion of the gate layer 310. In some examples, the high energy barrier height junction 334 and the low energy barrier height junction 336 may be as described with respect to FIG. 3.

The first metal portion (e.g., the portion of the metal layer contacting the upper surface of gate layer 310) and the second metal portion (e.g., portion of the metal layer contacting the sidewall surface of gate layer 310) may be a same metal. In some circumstances, a metal formed on a semiconductor material may react differently to thermal processing depending on whether the metal is on an upper surface or a sidewall surface of the semiconductor material. In some examples, a metal of the metal layer of the gate electrical contact 1622 reacts with an upper surface of the semiconductor material of the gate layer 310 differently than a sidewall surface of the semiconductor material of the gate layer 310. For example, upon undergoing thermal processing, such as an anneal, the metal may have more spiking through the sidewall surface than the upper surface. The different reactions may result in the high energy barrier height junction 334 and the low energy barrier height junction 336 as described above. As examples, the gate layer 310 may be a magnesium doped gallium nitride (GaN:Mg) layer with magnesium (Mg) doped at an activated concentration of 2×10¹⁸ cm⁻³, and the metal layer of the gate electrical contact 1622 may be titanium aluminum tungsten (TiAlW), titanium aluminum tungsten nitride (TiAlWN), or alloys thereof. Titanium aluminum tungsten (TiAlW) and titanium aluminum tungsten nitride (TiAlWN) may permit aluminum (Al) spiking in the sidewall surface of the semiconductor material of the gate layer 310.

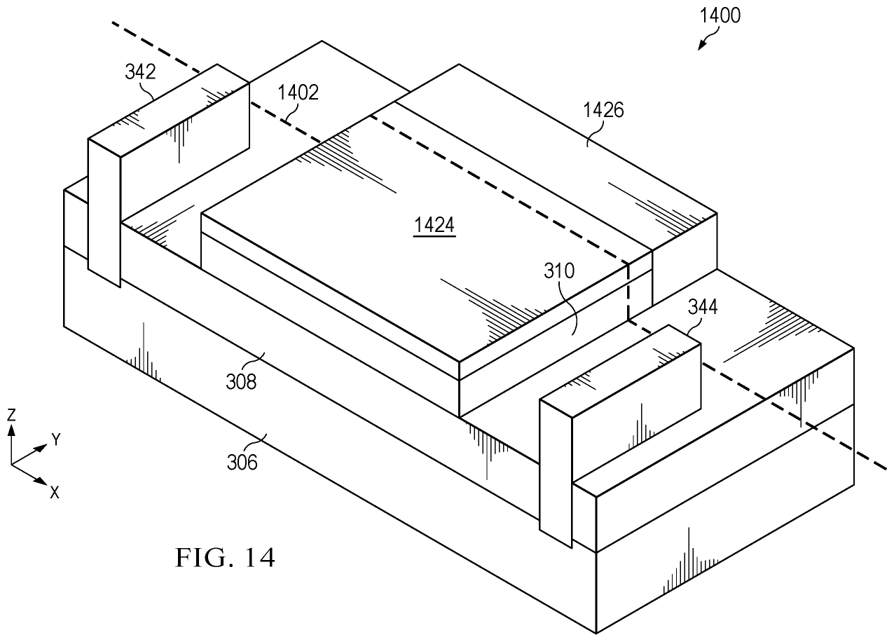

FIG. 17 is a perspective view of a semiconductor device 1700 according to some examples. The semiconductor device 1700 may be an implementation of the semiconductor device 1600 of FIG. 16. The semiconductor device 1700 as illustrated, includes the channel layer 306, the barrier layer 308, the gate layer 310, the source electrical contact 342, the drain electrical contact 344, and a gate electrical contact 1722. The gate electrical contact 1722 includes a first metal portion on an upper surface of the gate layer 310 and a second metal portion on a sidewall surface of the gate layer 310. The illustration of FIG. 17 shows the gate layer 310 extending in a channel width direction (e.g., a y-direction) beyond a lateral boundary 1702 (e.g., along an x-direction) of an active area. The first metal portion contacts the upper surface of the gate layer 310 at least within the boundary of the active area, and the second metal portion contacts the sidewall surface of the gate layer 310 outside of the lateral boundary 1702 of the active area. Having the second metal portion contact the sidewall surface of the gate layer 310 outside of the active area may increase a distance between (i) the second metal portion and (ii) the source electrical contact 342 and/or the drain electrical contact 344, which may reduce gate-to-source and gate-to-drain leakage. The gate electrical contact 1722 may result in lesser de-biasing of the of the gate current (I_{G}). By increasing a gate-to-source length (L_{GS}), the voltage drop (e.g., the current times resistance voltage drop) is increased in the gate-to-source length, and the effective gate overdrive voltage (V_{GT}) is reduced, which reduces the gate current (I_{G}).

FIG. 18 illustrates a cross-sectional view of a semiconductor device 1800 according to some examples. The semiconductor device 1800, in this example, is or includes a HEMT. Further, the semiconductor device 1800 may be or include an enhancement mode HEMT. Other examples may be or include other types of devices.

The semiconductor device 1800 of FIG. 18 includes at least some components of the semiconductor device 300 of FIG. 3 and includes a highly doped region 1802 and a gate electrical contact 1822. As described above, the gate layer 310 may be doped with a dopant (e.g., a p-type dopant). In the semiconductor device 1800 of FIG. 18, the gate layer 310 further includes a highly doped region 1802 that has an activated dopant concentration greater than any activated dopant concentration of the remaining portion of the gate layer 310. The highly doped region 1802 extends from a portion of the upper surface of the gate layer 310 into the gate layer 310. The highly doped region 1802 may be doped with a p-type dopant or an n-type dopant, which may be the same or different conductivity type dopant from what the remaining portion of the gate layer 310 is doped.

The gate electrical contact 1822 extends through the first dielectric layer 320 and contacts the gate layer 310. Lateral portions of the gate electrical contact 1822 may be over and on an upper surface of the first dielectric layer 320. The gate electrical contact 1822 includes a first metal portion and a second metal portion. In the illustrated example, the gate electrical contact 1822 is a metal layer, where the first metal portion includes a first portion of the metal layer, and the second metal portion includes a second portion of the metal layer. The metal layer of the gate electrical contact 1822 is conformally on an upper surface of the gate layer 310, sidewall surfaces of an opening through the first dielectric layer 320, and the upper surface of the first dielectric layer 320. The first portion of the metal layer contacts a first surface area of the upper surface of the gate layer 310 that is outside of the portion of the upper surface of the gate layer 310 from which the highly doped region 1802 extends. The second portion of the metal layer contacts a second surface area of the upper surface of the gate layer 310, which is the portion of the upper surface of the gate layer 310 from which the highly doped region 1802 extends. In some examples, the first surface area (e.g., where the metal layer contacts the upper surface of the gate layer 310 outside of the highly doped region 1802) is larger than the second surface area (e.g., where the metal layer contacts the upper surface of the gate layer 310 corresponding to the highly doped region 1802). For example, the first surface area may be at least 10 times larger than the second surface area, such as in a range from 10 to 100 times larger than the second surface area.

The first metal portion of the gate electrical contact 1822 (e.g., the portion of the metal layer contacting the upper surface of gate layer 310 outside of the highly doped region 1802) forms a high energy barrier height junction 334 with a first semiconductor portion of the gate layer 310 where the first metal portion contacts the first semiconductor portion of the gate layer 310. The second metal portion of the gate electrical contact 1822 (e.g., the portion of the metal layer contacting the upper surface of gate layer 310 corresponding to the highly doped region 1802) forms a low energy barrier height junction 336 with a second semiconductor portion (e.g., the highly doped region 1802) of the gate layer 310 where the second metal portion contacts the second semiconductor portion of the gate layer 310. In some examples, the high energy barrier height junction 334 and the low energy barrier height junction 336 may be as described with respect to FIG. 3.

The first metal portion (e.g., the portion of the metal layer contacting the upper surface of gate layer 310 outside of the highly doped region 1802) and the second metal portion (e.g., the portion of the metal layer contacting the upper surface of gate layer 310 corresponding to the highly doped region 1802) may be a same metal. The different doping of the gate layer 310 (e.g., an activated dopant concentration of the highly doped region 1802 compared to an activated dopant concentration of the remaining portion of the gate layer 310) may result in the high energy barrier height junction 334 and the low energy barrier height junction 336 as described above, such as when the first metal portion and the second metal portion are a same metal. As examples, the gate layer 310 may be a gallium nitride (GaN) layer; the highly doped region 1802 may be doped with magnesium (Mg) doped at an activated concentration of 2×10¹⁹ cm⁻³; a remaining portion of the gate layer 310 may be doped with magnesium (Mg) doped at an activated concentration of 2×10¹⁸ cm⁻³; and the metal layer of the gate electrical contact 1822 may be titanium aluminum tungsten (TiAlW), titanium aluminum tungsten nitride (TiAlWN), or alloys thereof.

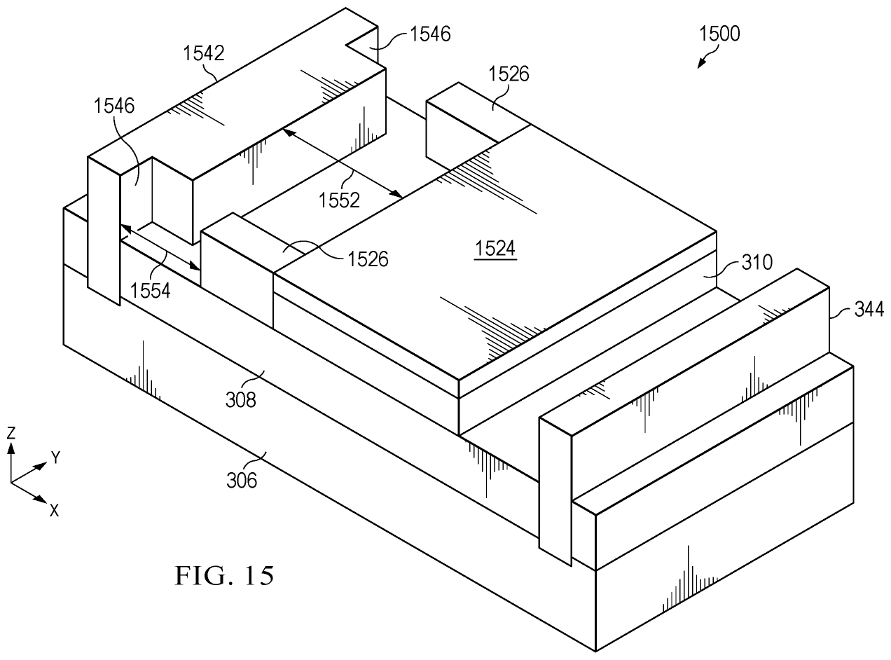

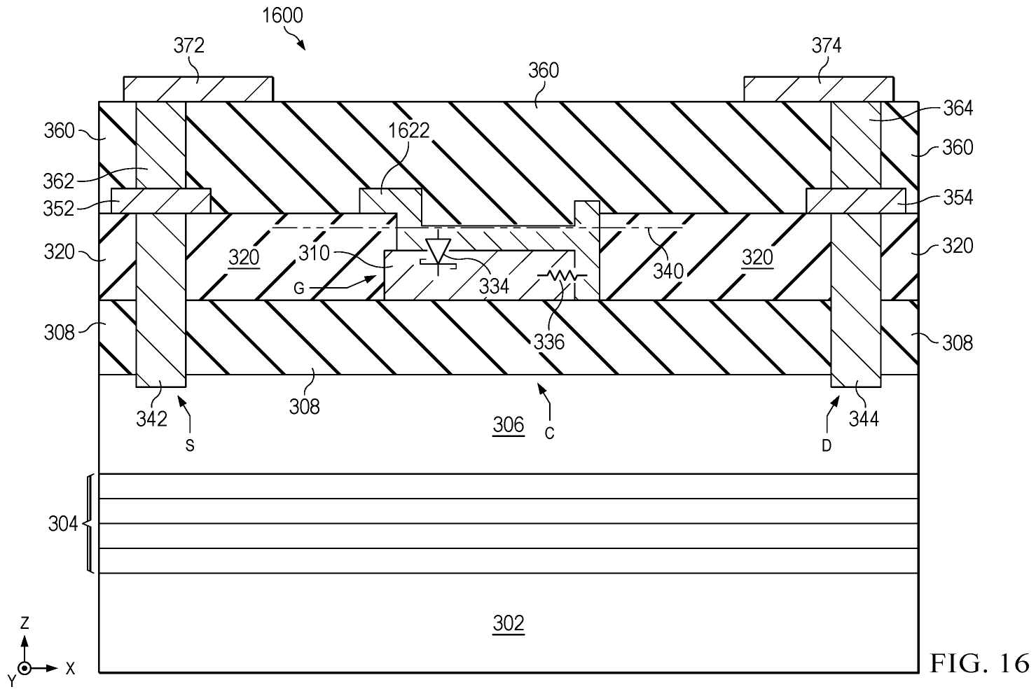

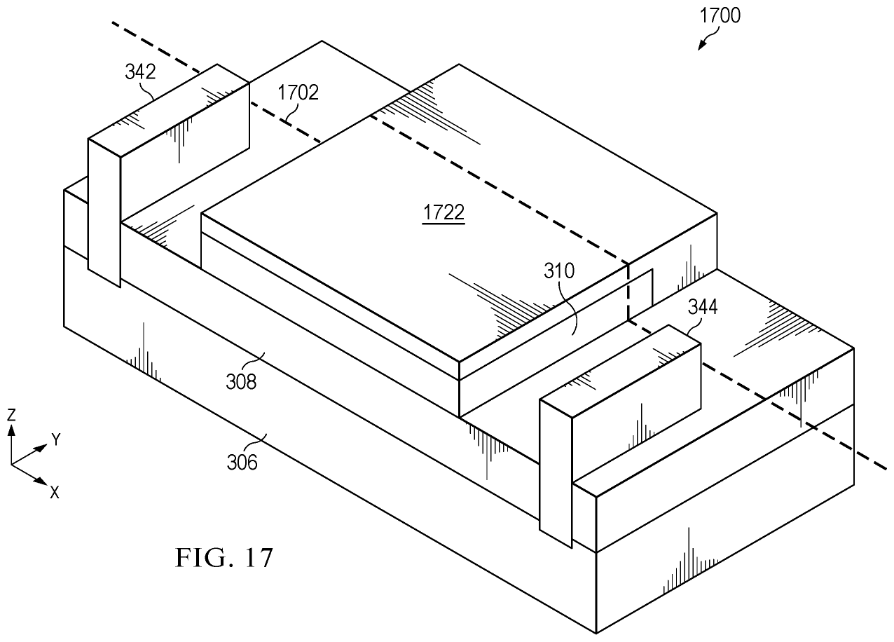

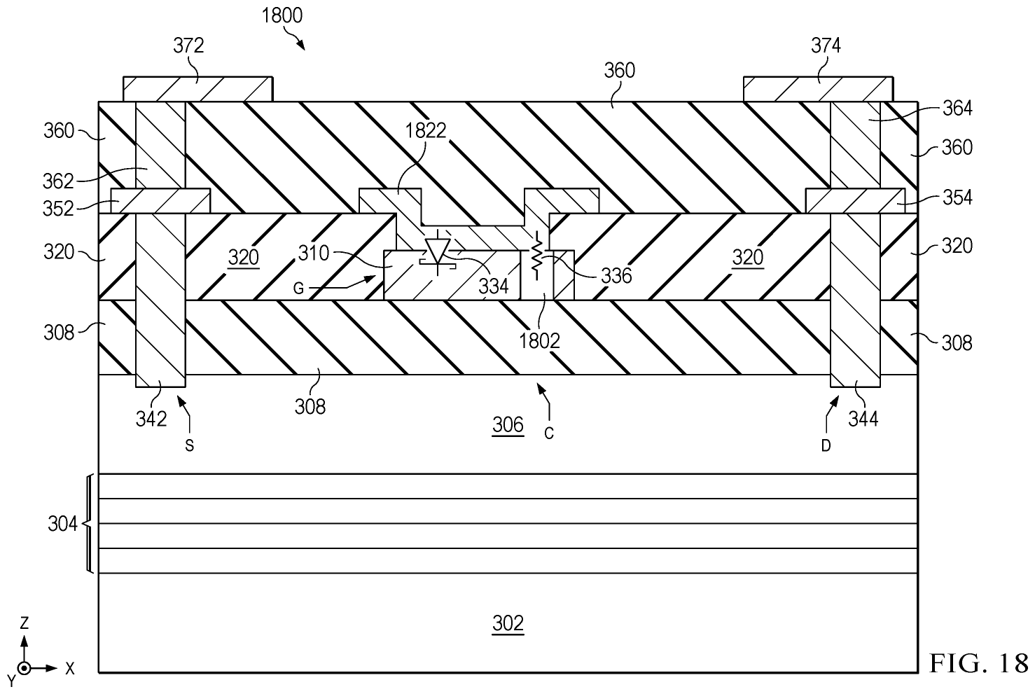

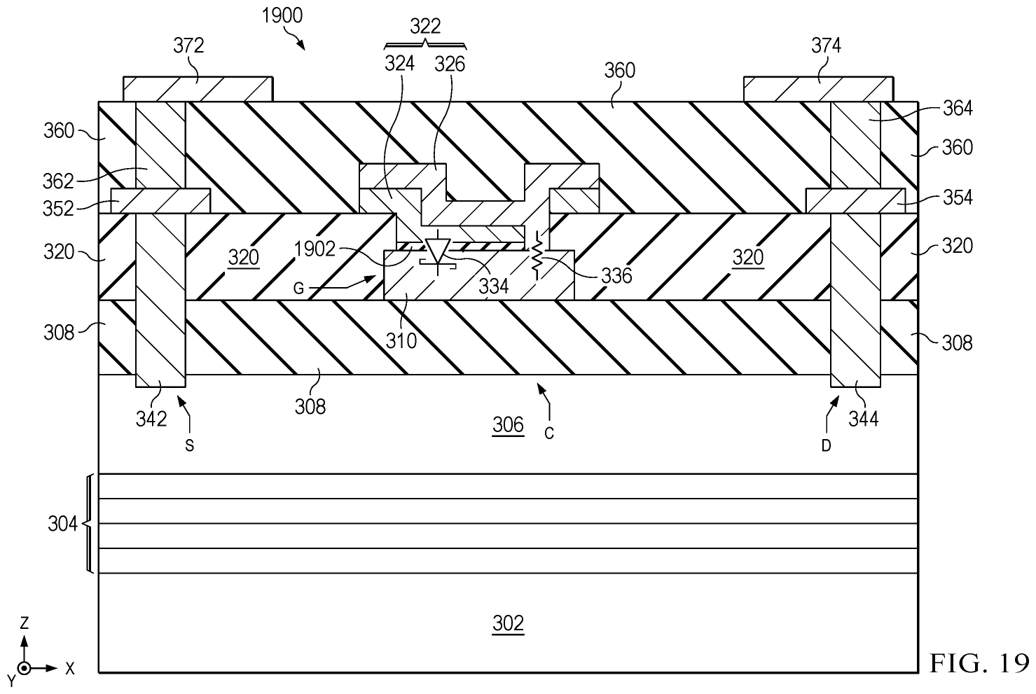

FIG. 19 illustrates a cross-sectional view of a semiconductor device 1900 according to some examples. The semiconductor device 1900, in this example, is or includes a HEMT. Further, the semiconductor device 1900 may be or include an enhancement mode HEMT. Other examples may be or include other types of devices.

The semiconductor device 1900 of FIG. 19 includes at least some components of the semiconductor device 300 of FIG. 3 and a dielectric layer 1902 between the gate layer 310 and the first metal layer 324. The dielectric layer 1902 may be any dielectric layer such as an oxide or a nitride, and more specifically, may be silicon oxide. The dielectric layer 1902 may have a thickness (e.g., in a direction normal to the upper surface of the gate layer 310) in a range from greater than 0 nanometers (nm) to less than or equal to 3 nm. For example, the dielectric layer 1902 may be a monolayer.

The dielectric layer 1902 can be between the first metal portion of a gate electrical contact and the first semiconductor portion of the gate layer 310. The dielectric layer 1902 may be included in any of the previously described semiconductor devices 300, 400, 500, 1100, 1200, 1300, 1600, 1800. The dielectric layer 1902 may increase an energy barrier height of the high energy barrier height junction 334. Further, the dielectric layer 1902 may further reduce gate current (I_{G}), which may compensate for an increase in gate current due to the low energy barrier height junction.

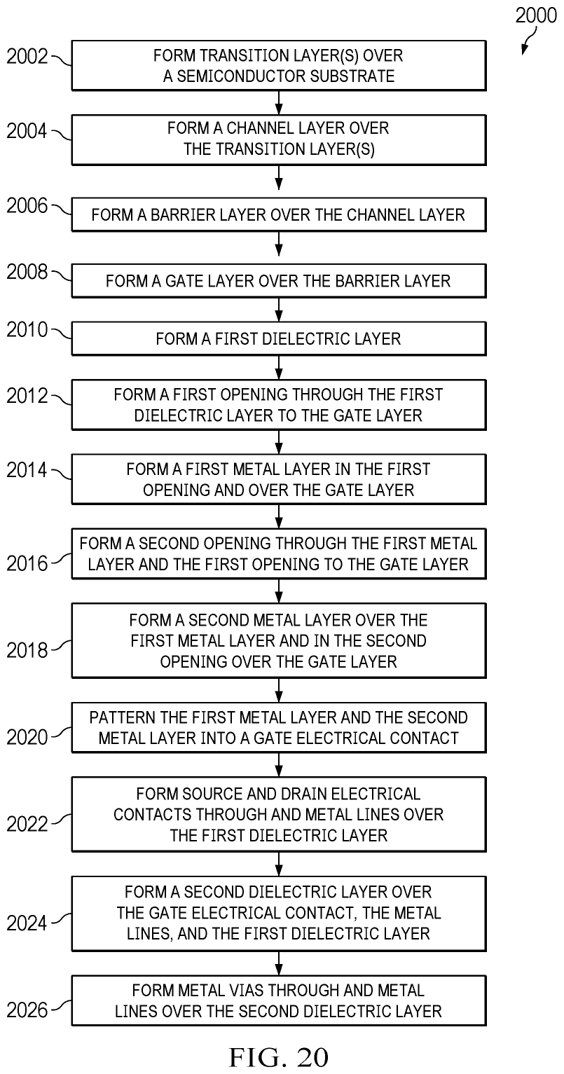

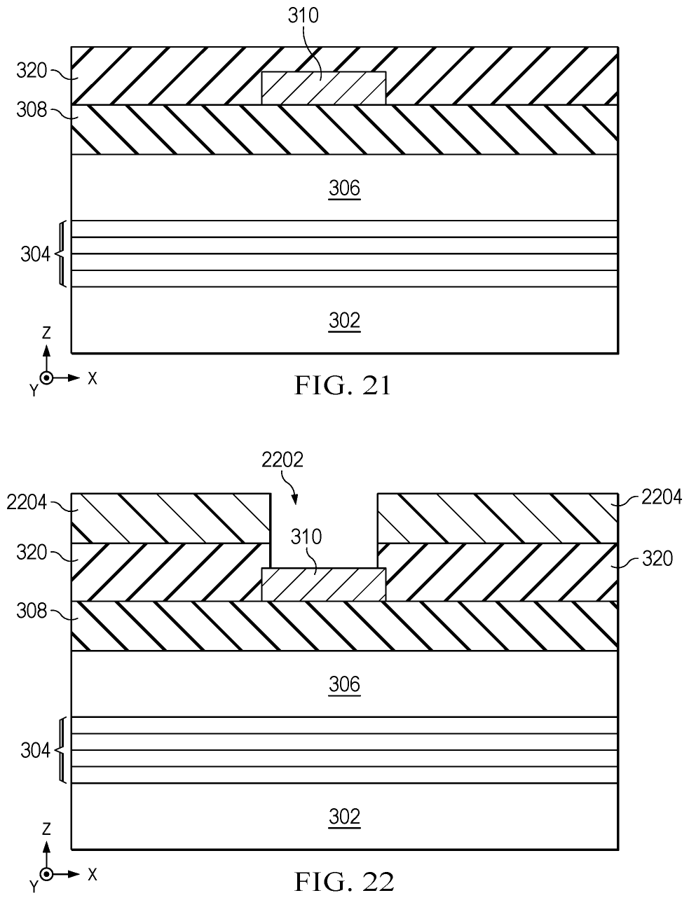

FIG. 20 is a flowchart of a method 2000 of manufacturing the semiconductor device 300 of FIG. 3 according to some examples. The method 2000 of FIG. 20 is illustrated by and described in the context of FIGS. 21 through 26, which illustrate cross sectional views of the semiconductor device 300 at various stages of manufacturing.

Referring to block 2002 of FIG. 20 and to FIG. 21, one or more transition layers 304 are formed over and on a semiconductor substrate 302. At block 2004, a channel layer 306 is formed over and on the transition layer(s) 304. At block 2006, a barrier layer 308 is formed over and on the channel layer 306. In some examples, the transition layer(s) 304, channel layer 306, and barrier layer 308 may be formed by using any appropriate deposition process, which may further be an epitaxial growth process. For example, the transition layer(s) 304, channel layer 306, and barrier layer 308 may each be epitaxially grown using metal-organic chemical vapor deposition (MOCVD), molecular beam epitaxy (MBE), low pressure chemical vapor deposition (LPCVD), or another epitaxy process. The materials of the semiconductor substrate 302, transition layer(s) 304, channel layer 306, and barrier layer 308 may be as described previously.

At block 2008, a gate layer 310 is formed over and on the barrier layer 308. In some examples, the gate layer 310 may be epitaxially grown, such as by MOCVD, MBE, LPCVD, plasma enhanced chemical vapor deposition (PECVD), atomic layer epitaxy, or another epitaxy process. The gate layer 310 may be doped in situ during deposition (e.g., epitaxial growth) or by implantation (e.g., ion implantation) subsequent to deposition. After deposition, the gate layer 310 is patterned. The gate layer 310 may be patterned using appropriate photolithography and etch processes. For example, to pattern the gate layer 310, a photoresist is deposited (e.g., by spin-on) over and/or on the semiconductor substrate 302 (e.g., over and/or on the gate layer 310) and patterned using photolithography. The photoresist is patterned to remain in an area corresponding to an area where the gate structure G is to be formed. With the patterned photoresist, an etch process, such as an anisotropic etch like a reactive ion etch (RIE) or the like, is performed, using the patterned photoresist as a mask, to pattern the gate layer 310. After the etch process, the photoresist is removed, such as by ashing. The materials of the gate layer 310, any dopant, and any concentration of a dopant may be as described previously.

At block 2010, a first dielectric layer 320 is formed over and on the gate layer 310 and the barrier layer 308. The first dielectric layer 320 may be deposited using any appropriate deposition process, such as LPCVD, PECVD, or the like. The material(s) of the first dielectric layer 320 may be as described above. The first dielectric layer 320 may be planarized, such as by a chemical mechanical polish (CMP).

Referring to block 2012 and to FIG. 22, a first opening 2202 is formed through the first dielectric layer 320 to the gate layer 310. The first opening 2202 is formed to and exposes the upper surface of the gate layer 310. The first opening 2202 may be formed using appropriate photolithography and etch processes. For example, to form the first opening 2202 a photoresist 2204 is deposited (e.g., by spin-on) over and/or on the semiconductor substrate 302 (e.g., over and/or on the first dielectric layer 320) and patterned using photolithography. The photoresist 2204 is patterned to expose an area where the first opening 2202 is to be formed. With the patterned photoresist 2204 being used as a mask, an etch process, such as an anisotropic etch like a RIE or the like, is performed to form the first opening 2202. After the etch process, the photoresist 2204 is removed, such as by ashing.

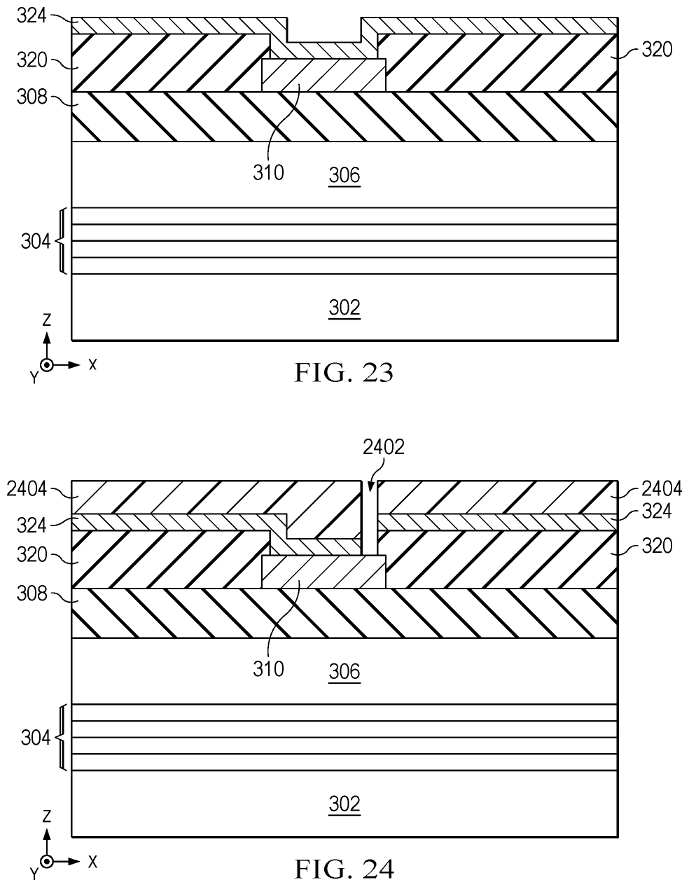

Referring to block 2014 and to FIG. 23, a first metal layer 324 is formed in the first opening 2202 and over and on the gate layer 310. The first metal layer 324 is conformally deposited over and on the upper surface of the first dielectric layer 320, along sidewall surfaces of the first dielectric layer 320 that define the first opening 2202, and over and on the upper surface of the gate layer 310 exposed by the first opening 2202. The first metal layer 324 may be deposited using any appropriate deposition process, such as chemical vapor deposition (CVD), physical vapor deposition (PVD), or the like. The first metal layer 324 may include or be a material as described above.

Referring to block 2016 and to FIG. 24, a second opening 2402 is formed through the first metal layer 324 and the first opening 2202 to the gate layer 310. The second opening 2402 is formed to and exposes the upper surface of the gate layer 310. The second opening 2402 may be formed using appropriate photolithography and etch processes. For example, to form the second opening 2402 a photoresist 2404 is deposited (e.g., by spin-on) over and/or on the semiconductor substrate 302 (e.g., over and/or on the first metal layer 324) and patterned using photolithography. The photoresist 2404 is patterned to expose an area where the second opening 2402 is to be formed. With the patterned photoresist 2404 being used as a mask, an etch process, such as an anisotropic etch like a RIE or the like, is performed to form the second opening 2402. After the etch process, the photoresist 2404 is removed, such as by ashing.

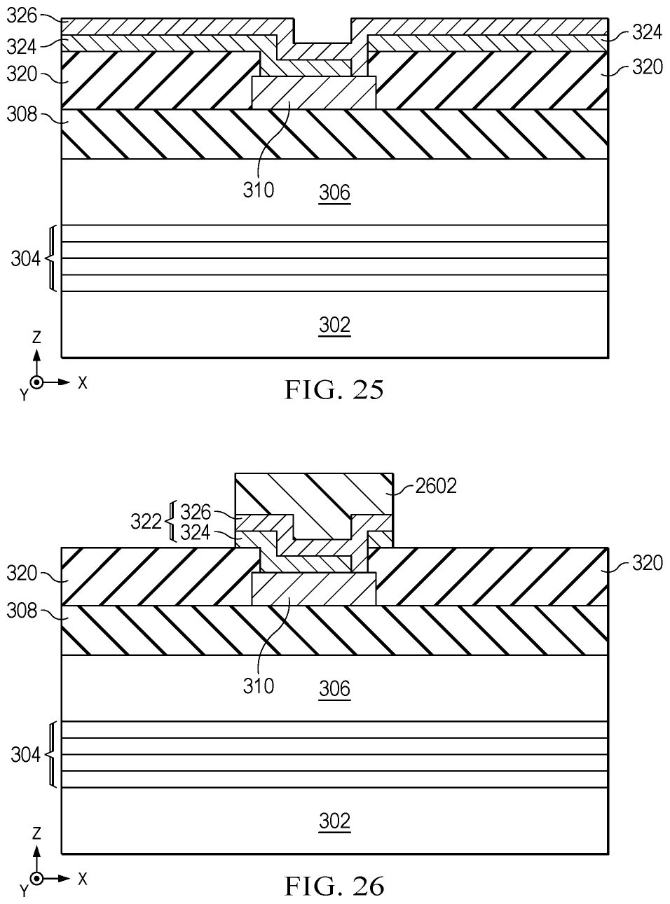

Referring to block 2018 and to FIG. 25, a second metal layer 326 is formed over and on the first metal layer 324 and in the second opening 2402 over and on the gate layer 310. The second metal layer 326 is conformally deposited over and on the first metal layer 324, along sidewall surfaces of the first dielectric layer 320 and first metal layer 324 that define the second opening 2402, and over and on the upper surface of the gate layer 310 exposed by the second opening 2402. The second metal layer 326 may be deposited using any appropriate deposition process, such as CVD, PVD, or the like. The second metal layer 326 may include or be a material as described above.

Referring to block 2020 and to FIG. 26, the first metal layer 324 and the second metal layer 326 are patterned into a gate electrical contact 322. The first metal layer 324 and the second metal layer 326 may be patterned using appropriate photolithography and etch processes. For example, to pattern the first metal layer 324 and the second metal layer 326 into the gate electrical contact 322, a photoresist 2602 is deposited (e.g., by spin-on) over and/or on the semiconductor substrate 302 (e.g., over and/or on the second metal layer 326) and patterned using photolithography. The photoresist 2602 is patterned to remain in an area corresponding to an area where the gate electrical contact 322 is to be formed. With the patterned photoresist 2602 being used as a mask, an etch process, such as an anisotropic etch like a RIE or the like, is performed to pattern the first metal layer 324 and the second metal layer 326 into the gate electrical contact 322. After the etch process, the photoresist 2602 is removed, such as by ashing.

Referring to block 2022 and to FIG. 3, a source electrical contact 342 and a drain electrical contact 344 are formed through the first dielectric layer 320, and metal lines 352, 354 are formed over and on the first dielectric layer 320. For example, contact openings may be formed through the first dielectric layer 320 to the channel layer 306. The contact openings may be formed using appropriate photolithography and etch processes. One or more metals are deposited into the contact openings and over and on an upper surface of the first dielectric layer 320. The one or more metals deposited into the contact openings form the source electrical contact 342 and the drain electrical contact 344. The metal(s) may be deposited using an appropriate deposition process(es), such as CVD, PVD, or the like. The metal(s) over the upper surface of the first dielectric layer 320 are patterned into the metal lines 352, 354. The metal lines 352, 354 may be patterned using appropriate photolithography and etch processes. At block 2024, a second dielectric layer 360 is formed over and on the gate electrical contact 322, the metal lines 352, 354, and the first dielectric layer 320. The second dielectric layer 360 may be deposited using any appropriate deposition process, such as PECVD or the like. The second dielectric layer 360 may be planarized, such as by a CMP.

At block 2026, metal vias 362, 364 are formed through the second dielectric layer 360, and metal lines 372, 374 are formed over and on the second dielectric layer 360. Openings may be formed through the second dielectric layer 360 to the metal lines 352, 354 using appropriate photolithography and etching processes. A metal(s) of the metal vias 362, 364 and metal lines 372, 374 are deposited over the second dielectric layer 360 and in the openings through the second dielectric layer 360. The metal(s) may be deposited using an appropriate deposition process(es), such as CVD, PVD, or the like. The metal(s) may be patterned into the metal lines 372, 374 using appropriate photolithography and etching processes. The metal(s) underlying the metal lines 372, 374 and in the respective openings through the second dielectric layer 360 form the metal vias 362, 364.

Photolithography and etch processes are described briefly subsequently, where appropriate, in view of the previous description.

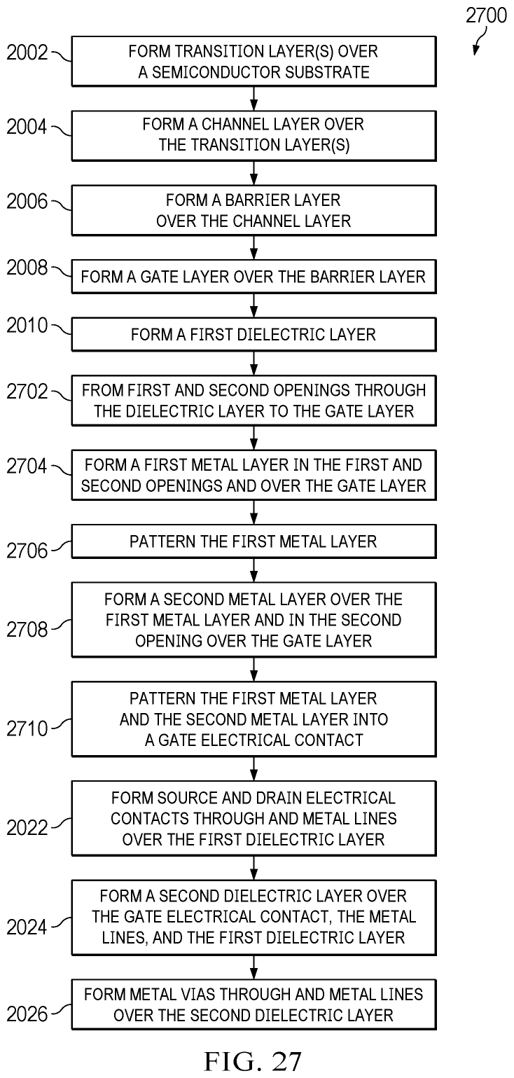

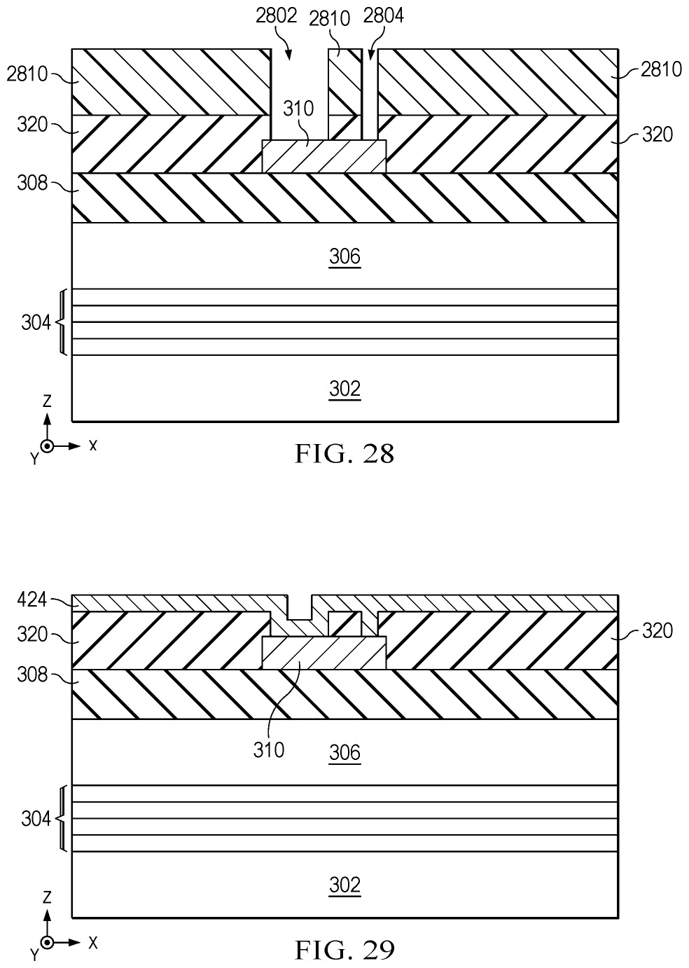

FIG. 27 is a flowchart of a method 2700 of manufacturing the semiconductor device 400 of FIG. 4 according to some examples. The method 2700 of FIG. 27 is illustrated by and described in the context of FIGS. 28 through 32, which illustrate cross-sectional views of the semiconductor device 400 at various stages of manufacturing.

Processing proceeds at blocks 2002, 2004, 2006, 2008, 2010 as described with respect to FIG. 21. Referring to block 2702 and to FIG. 28, a first opening 2802 and a second opening 2804 are formed through the first dielectric layer 320 to the gate layer 310. The first opening 2802 and the second opening 2804 are formed to and expose the upper surface of the gate layer 310. The first opening 2802 and second opening 2804 may be formed using appropriate photolithography and etch processes (e.g., using a photoresist 2810).

Referring to block 2704 and to FIG. 29, a first metal layer 424 is formed in the first opening 2802 and the second opening 2804 and over and on the gate layer 310. The first metal layer 424 is conformally deposited over and on the upper surface of the first dielectric layer 320, along sidewall surfaces of the first dielectric layer 320 that define the first opening 2802 and the second opening 2804, and over and on the upper surface of the gate layer 310 exposed by the first opening 2802 and the second opening 2804. The first metal layer 424 may be deposited using any appropriate deposition process. The first metal layer 424 may include or be a material as described above.

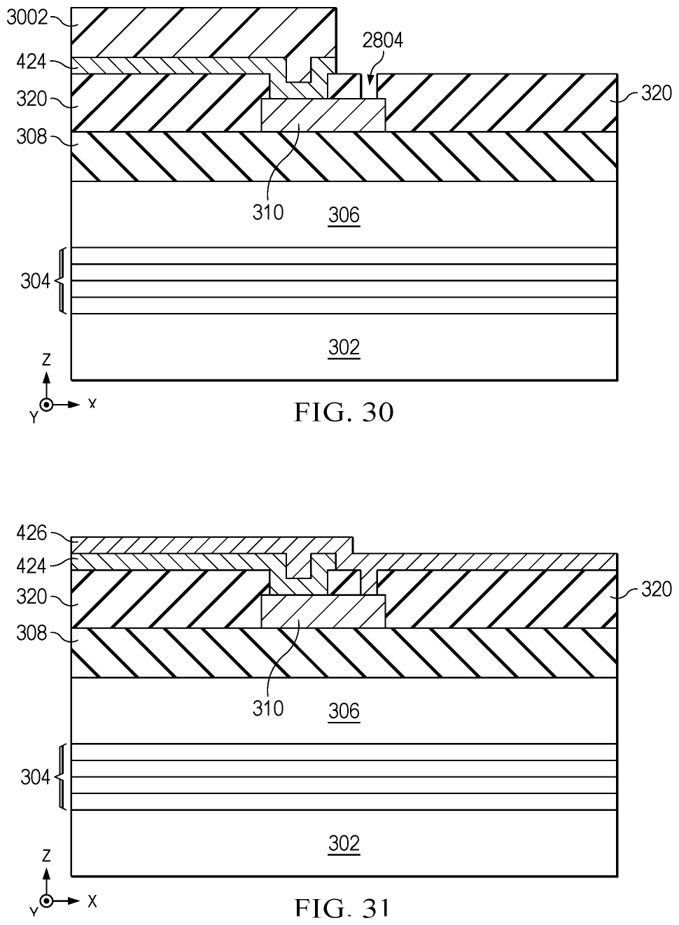

Referring to block 2706 and to FIG. 30, the first metal layer 424 is patterned. The first metal layer 424 is patterned to remove the first metal layer from the second opening 2804 through the first dielectric layer 320. The first metal layer 424 may be patterned using appropriate photolithography and etch processes (e.g., using a photoresist 3002).

Referring to block 2708 and to FIG. 31, a second metal layer 426 is formed over and on the first metal layer 424 and in the second opening 2804 over and on the gate layer 310. The second metal layer 426 is conformally deposited over and on the first metal layer 424, along sidewall surfaces of the first dielectric layer 320 that define the second opening 2804, and over and on the upper surface of the gate layer 310 exposed by the second opening 2804. The second metal layer 426 may be deposited using any appropriate deposition process. The second metal layer 426 may include or be a material as described above.

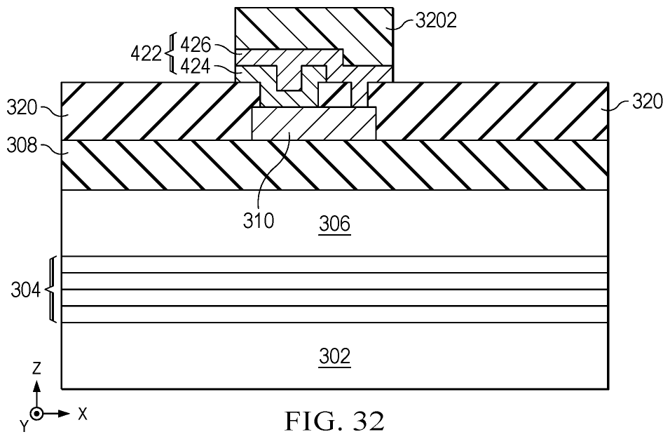

Referring to block 2710 and to FIG. 32, the first metal layer 424 and the second metal layer 426 are patterned into a gate electrical contact 422. The first metal layer 424 and the second metal layer 426 may be patterned using appropriate photolithography and etch processes (e.g., using a photoresist 3202). Processing continues at blocks 2022, 2024, 2026 as described with respect to FIG. 3.

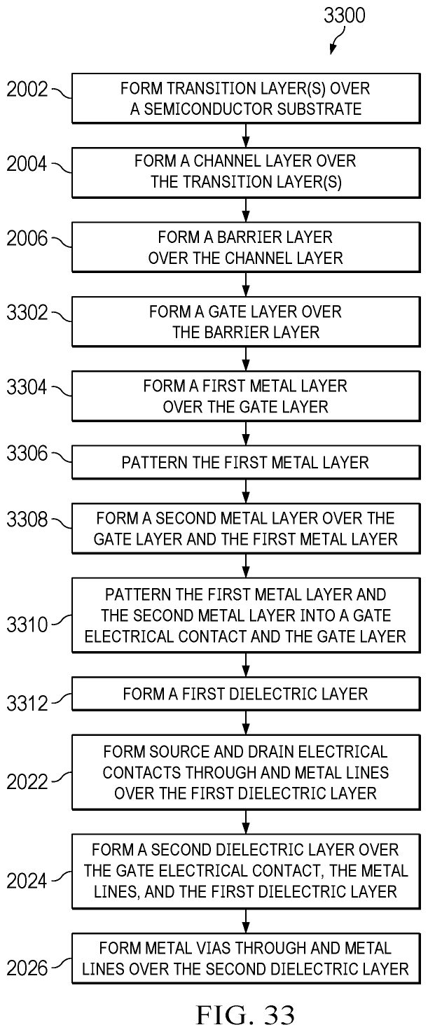

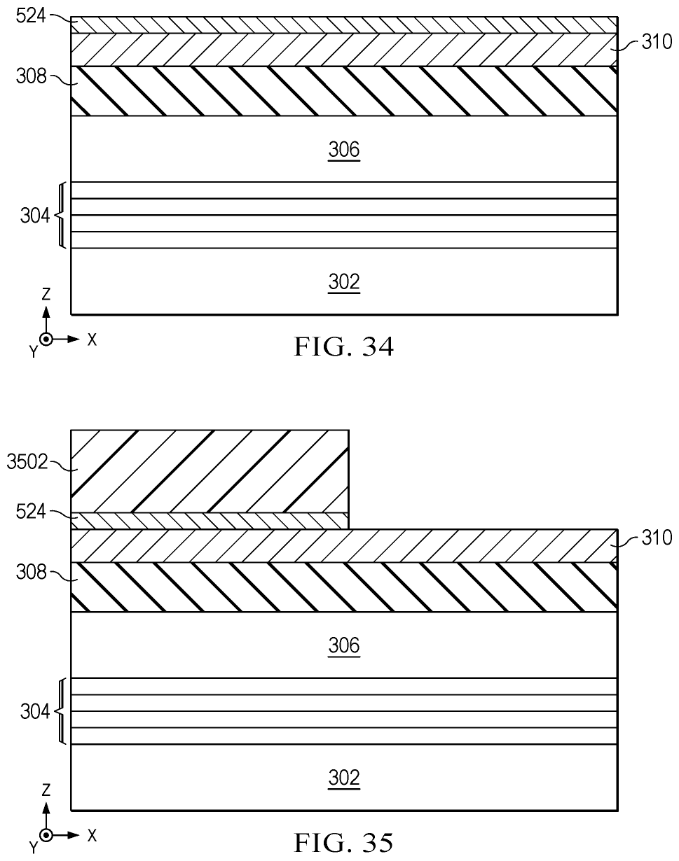

FIG. 33 is a flowchart of a method 3300 of manufacturing the semiconductor device 500 of FIG. 5 according to some examples. The method 3300 of FIG. 33 is illustrated by and described in the context of FIGS. 34 through 38, which illustrate cross-sectional views of the semiconductor device 500 at various stages of manufacturing.

Processing proceeds at blocks 2002, 2004, 2006 as described with respect to FIG. 21. Referring block 3302 and FIG. 34, the gate layer 310 is formed over and on the barrier layer 308. The gate layer 310 may be deposited using any appropriate deposition process. The gate layer 310 may include or be a material as described above. At block 3304, a first metal layer 524 is formed over and on the gate layer 310. The first metal layer 524 may be deposited using any appropriate deposition process. The first metal layer 524 may include or be a material as described above.

Referring to block 3306 and to FIG. 35, the first metal layer 524 is patterned. The first metal layer 524 is patterned to remove the first metal layer 524 from an area over the gate layer 310 that will form a portion of the gate structure. The first metal layer 524 may be patterned using appropriate photolithography and etch processes (e.g., using a photoresist 3502).

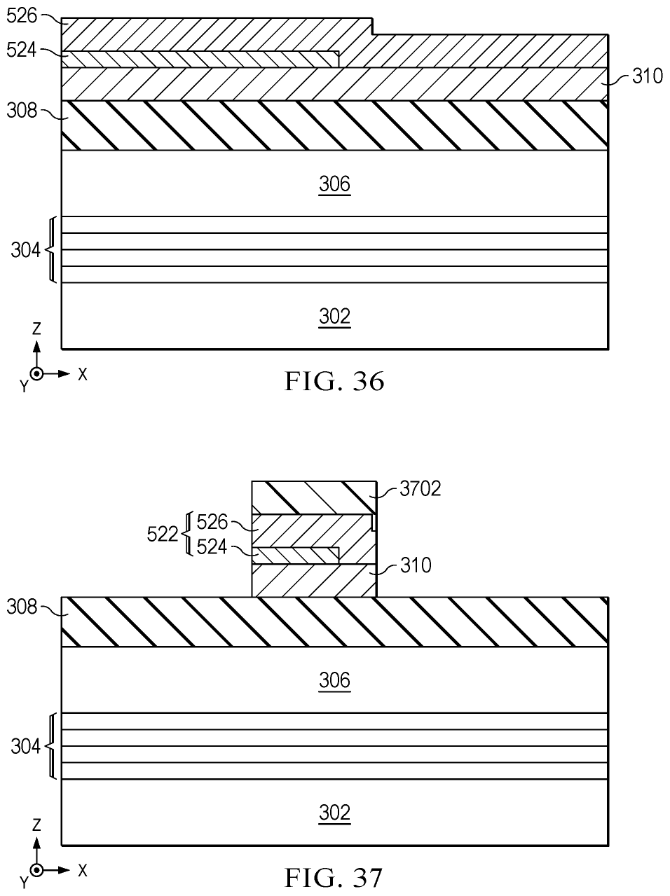

Referring to block 3308 and to FIG. 36, a second metal layer 526 is formed over and on the gate layer 310 and the first metal layer 524. The second metal layer 526 may be deposited using any appropriate deposition process. The second metal layer 526 may include or be a material as described above.

Referring to block 3310 and to FIG. 37, the first metal layer 524 and the second metal layer 526 are patterned into a gate electrical contact 522, and the gate layer 310 is patterned. The first metal layer 524, the second metal layer 526, and the gate layer 310 may be patterned using appropriate photolithography and etch processes (e.g., using a photoresist 3702). The patterning of the second metal layer 526, the first metal layer 524, and the gate layer 310 may form the gate electrical contact 522 to be self-aligned with the gate layer 310.

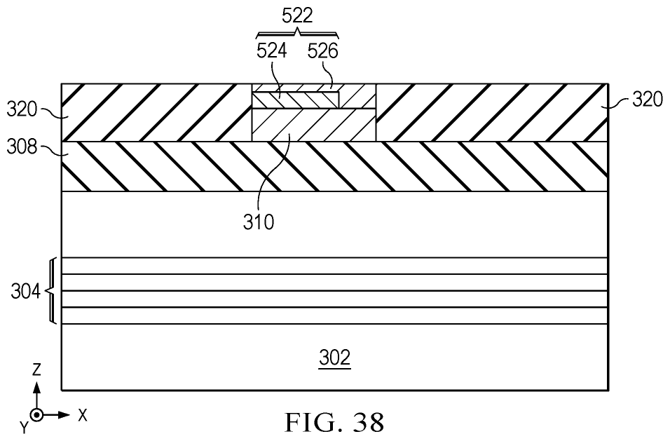

Referring to block 3312 and to FIG. 38, a first dielectric layer 320 is formed over and on the barrier layer 308 and along the gate electrical contact 522. The gate electrical contact 522 may be exposed through an upper surface of the first dielectric layer 320. The first dielectric layer 320 may be deposited using any appropriate deposition process. The material(s) of the first dielectric layer 320 may be as described above. The first dielectric layer 320 may be planarized, such as by a CMP, which may result in the gate electrical contact 522 being exposed through the upper surface of the first dielectric layer 320. Processing continues at blocks 2022, 2024, 2026 as described with respect to FIG. 3.

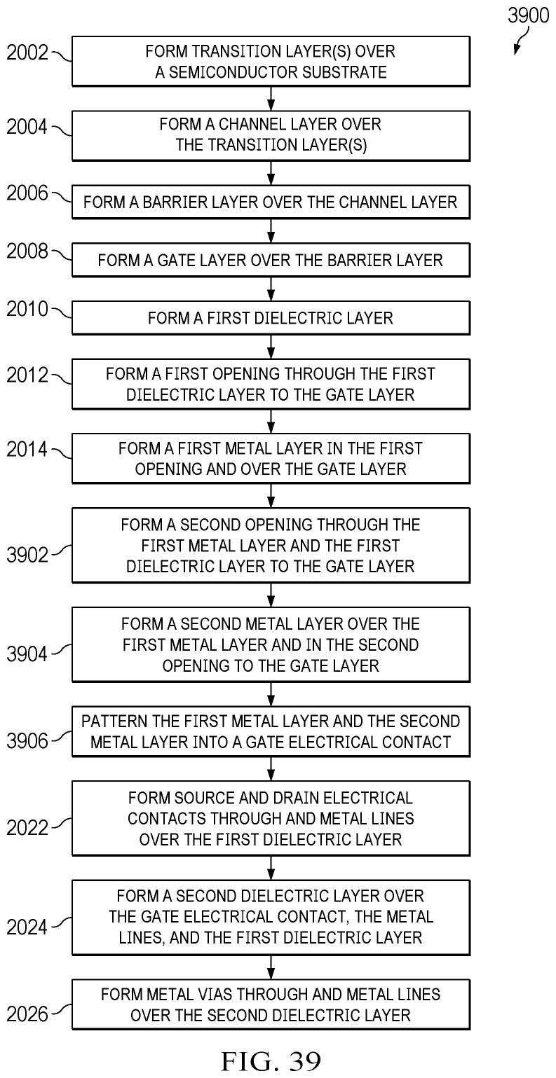

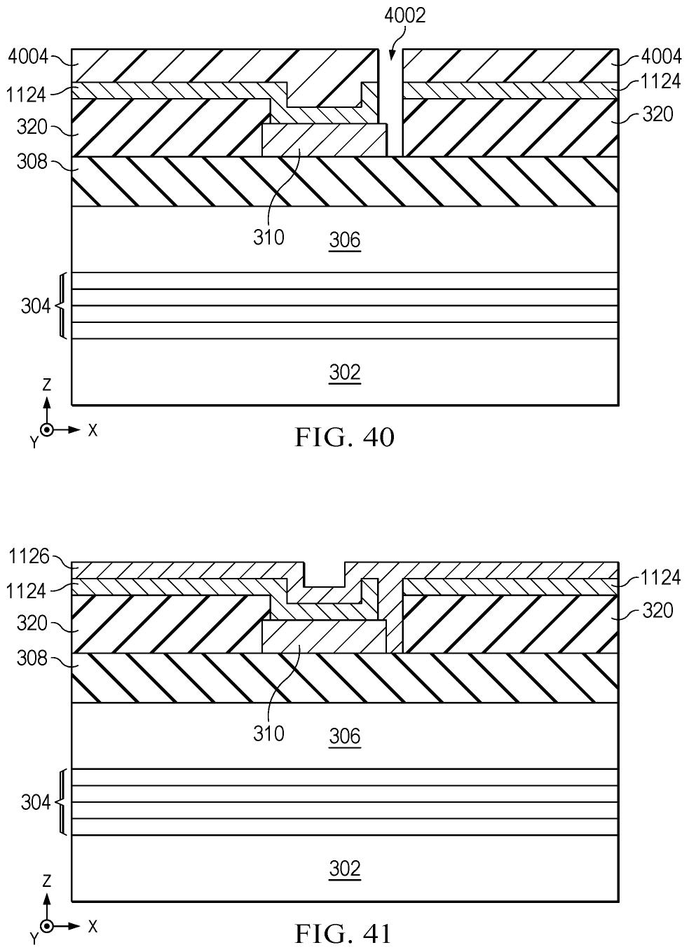

FIG. 39 is a flowchart of a method 3900 of manufacturing the semiconductor device 1100 of FIG. 11 according to some examples. The method 3900 of FIG. 39 is illustrated by and described in the context of FIGS. 40 through 42, which illustrate cross-sectional views of the semiconductor device 1100 at various stages of manufacturing.

Processing proceeds at blocks 2002, 2004, 2006, 2008, 2010, 2012, 2014 as described with respect to FIGS. 21, 22, and 23 (with the first metal layer 1124 as the first metal layer 324). Referring to block 3902 and to FIG. 40, a second opening 4002 is formed through the first metal layer 1124 and the first dielectric layer 320 to the gate layer 310. The second opening 4002 is formed to and exposes a sidewall surface of the gate layer 310. The second opening 4002 may be formed using appropriate photolithography and etch processes (e.g., using a photoresist 4004).

Referring to block 3904 and to FIG. 41, a second metal layer 1126 is formed over and on the first metal layer 1124 and in the second opening 4002 on the sidewall surface of the gate layer 310. The second metal layer 1126 is conformally deposited over and on the first metal layer 1124 and along sidewall surfaces of the first dielectric layer 320, first metal layer 1124, and gate layer 310 that define the second opening 4002. The second metal layer 1126 may be deposited using any appropriate deposition process. The second metal layer 1126 may include or be a material as described above.

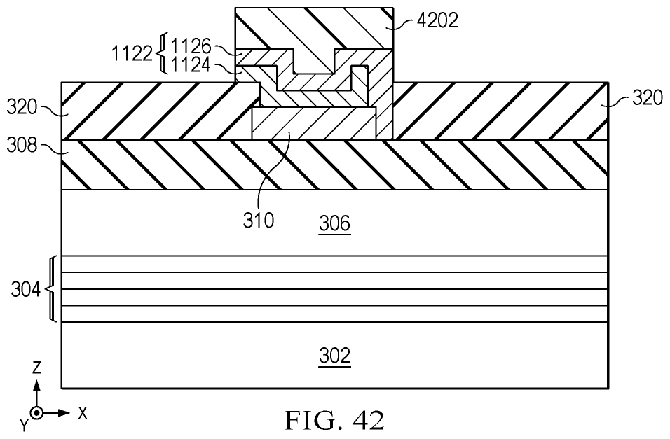

Referring to block 3906 and to FIG. 42, the first metal layer 1124 and the second metal layer 1126 are patterned into a gate electrical contact 1122. The first metal layer 1124 and the second metal layer 1126 may be patterned using appropriate photolithography and etch processes (e.g., using a photoresist 4202). Processing continues at blocks 2022, 2024, 2026 as described with respect to FIG. 3.

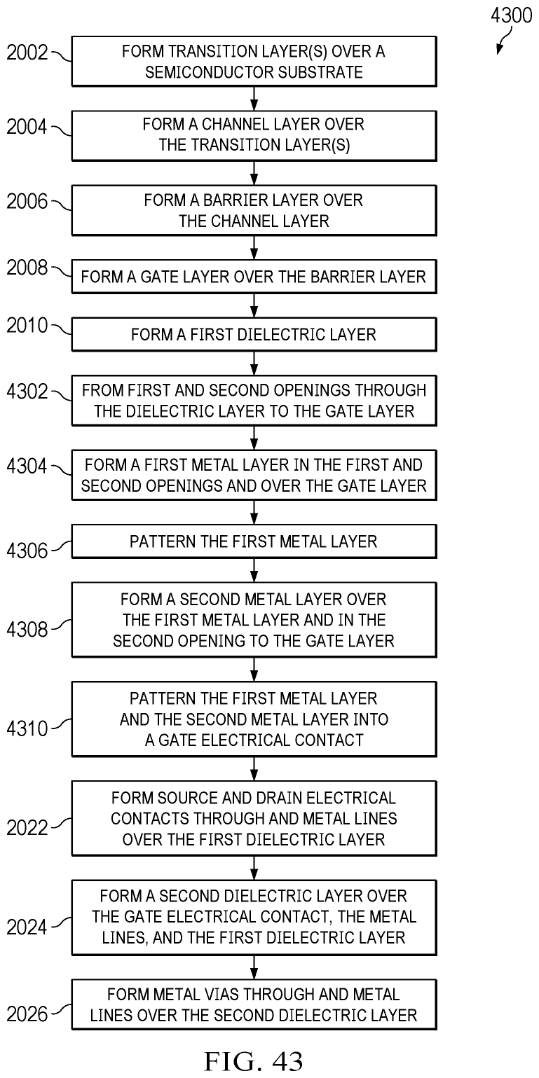

FIG. 43 is a flowchart of a method 4300 of manufacturing the semiconductor device 1200 of FIG. 12 according to some examples. The method 4300 of FIG. 43 is illustrated by and described in the context of FIGS. 44 through 48, which illustrate cross-sectional views of the semiconductor device 1200 at various stages of manufacturing.

Processing proceeds at blocks 2002, 2004, 2006, 2008, 2010 as described with respect to FIG. 21. Referring to block 4302 and to FIG. 44, a first opening 4402 and a second opening 4404 are formed through the first dielectric layer 320 to the gate layer 310. The first opening 4402 is formed to and exposes the upper surface of the gate layer 310. The second opening 4404 is formed to and exposes a sidewall surface of the gate layer 310. The first opening 4402 and second opening 4404 may be formed using appropriate photolithography and etch processes (e.g., using a photoresist 4410).

Referring to block 4304 and to FIG. 45, a first metal layer 1224 is formed in the first opening 4402 and the second opening 4404 and over and on the gate layer 310. The first metal layer 1224 is conformally deposited over and on the upper surface of the first dielectric layer 320, along sidewall surfaces of the first dielectric layer 320 that define the first opening 4402, over and on the upper surface of the gate layer 310 exposed by the first opening 4402, and along sidewall surfaces of the first dielectric layer 320 and gate layer 310 that define the second opening 4404. The first metal layer 1224 may be deposited using any appropriate deposition process. The first metal layer 1224 may include or be a material as described above.

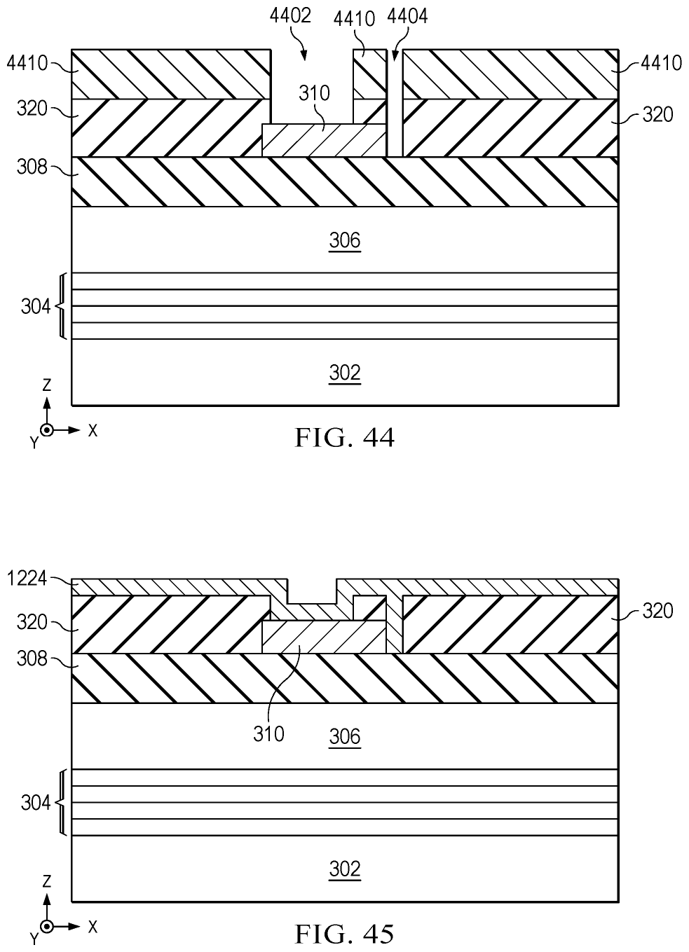

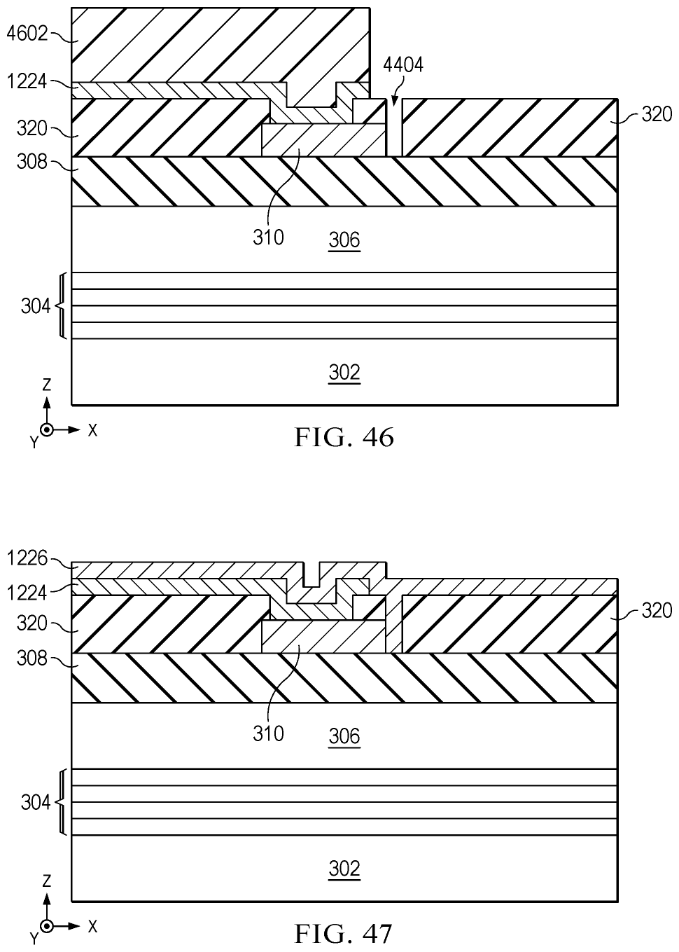

Referring to block 4306 and to FIG. 46, the first metal layer 1224 is patterned. The first metal layer 1224 is patterned to remove the first metal layer 1224 from the second opening 4404 through the first dielectric layer 320. The first metal layer 1224 may be patterned using appropriate photolithography and etch processes (e.g., using a photoresist 4602).

Referring to block 4308 and to FIG. 47, a second metal layer 1226 is formed over and on the first metal layer 1224 and in the second opening 4404 along the sidewall surface of the gate layer 310. The second metal layer 1226 is conformally deposited over and on the first metal layer 1224 and along sidewall surfaces of the first dielectric layer 320 and gate layer 310 that define the second opening 4404. The second metal layer 1226 may be deposited using any appropriate deposition process. The second metal layer 1226 may include or be a material as described above.

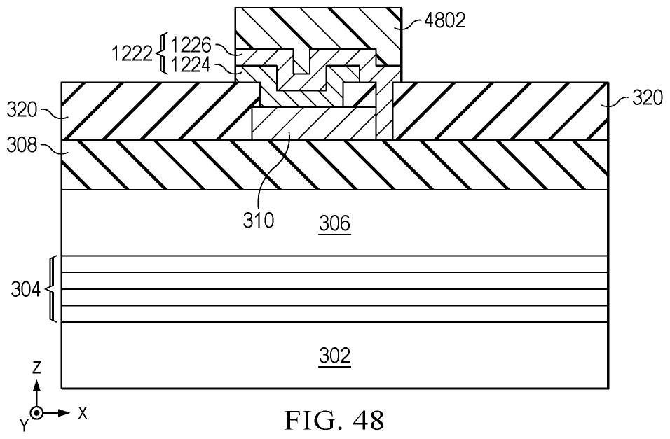

Referring to block 4310 and to FIG. 48, the first metal layer 1224 and the second metal layer 1226 are patterned into a gate electrical contact 1222. The first metal layer 1224 and the second metal layer 1226 may be patterned using appropriate photolithography and etch processes (e.g., using a photoresist 4802). Processing continues at blocks 2022, 2024, 2026 as described with respect to FIG. 3.

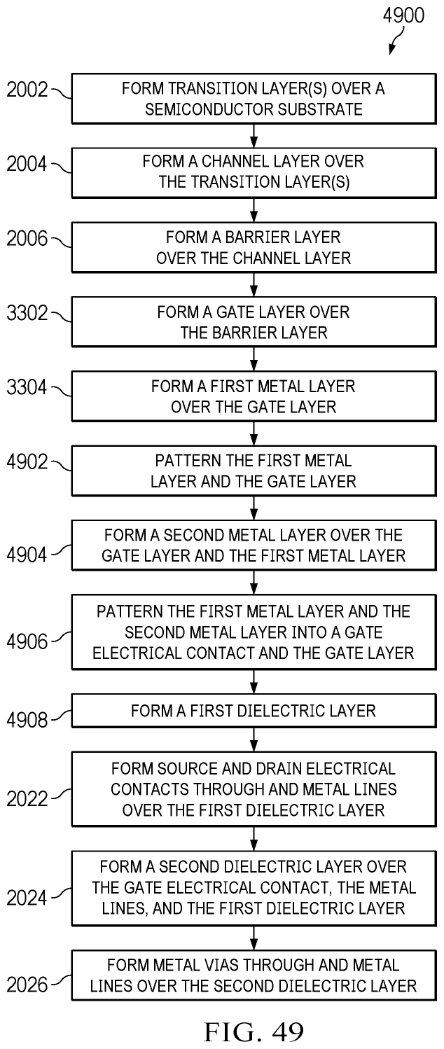

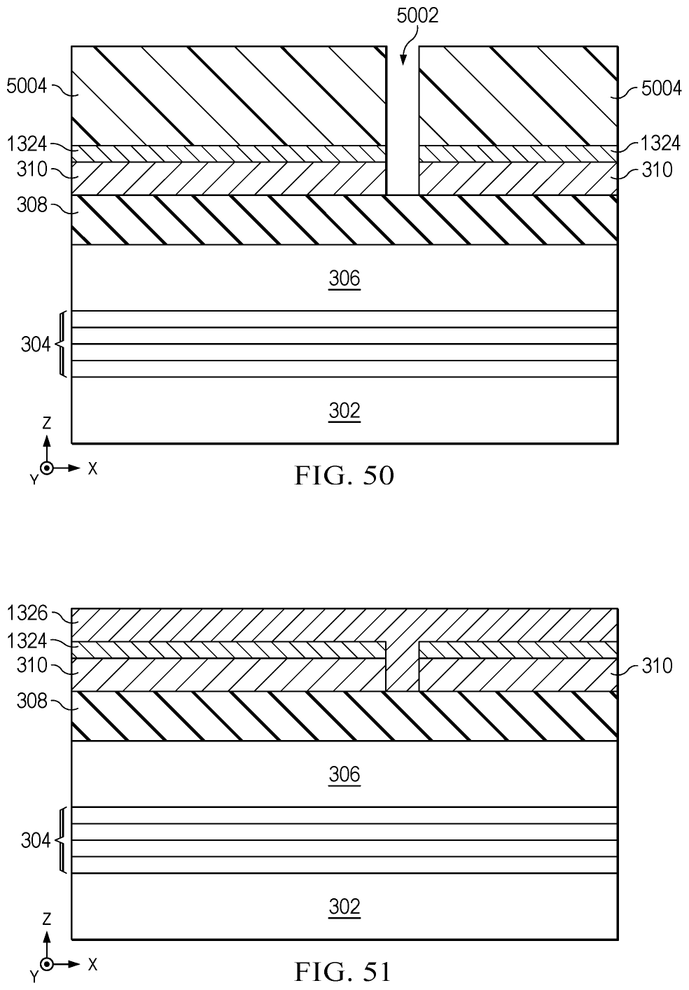

FIG. 49 is a flowchart of a method 4900 of manufacturing the semiconductor device 1300 of FIG. 13 according to some examples. The method 4900 of FIG. 49 is illustrated by and described in the context of FIGS. 50 through 53, which illustrate cross-sectional views of the semiconductor device 1300 at various stages of manufacturing.

Processing proceeds at blocks 2002, 2004, 2006 as described with respect to FIG. 21 and blocks 3302, 3304 as described with respect to FIG. 34 (with the first metal layer 1324 as the first metal layer 524). Referring to block 4902 and to FIG. 50, the first metal layer 1324 and the gate layer 310 are patterned, such as with an opening 5002 therethrough. The patterning forms a sidewall surface of the gate layer 310 that will form a portion of the gate structure. The first metal layer 1324 and the gate layer may be patterned using appropriate photolithography and etch processes (e.g., using a photoresist 5004).

Referring to block 4904 and to FIG. 51, a second metal layer 1326 is formed over and on the gate layer 310 and the first metal layer 1324. The second metal layer 1326 is formed in the opening 5002 and along the sidewall surface of the gate layer 310. The second metal layer 1326 may be deposited using any appropriate deposition process. The second metal layer 1326 may include or be a material as described above.

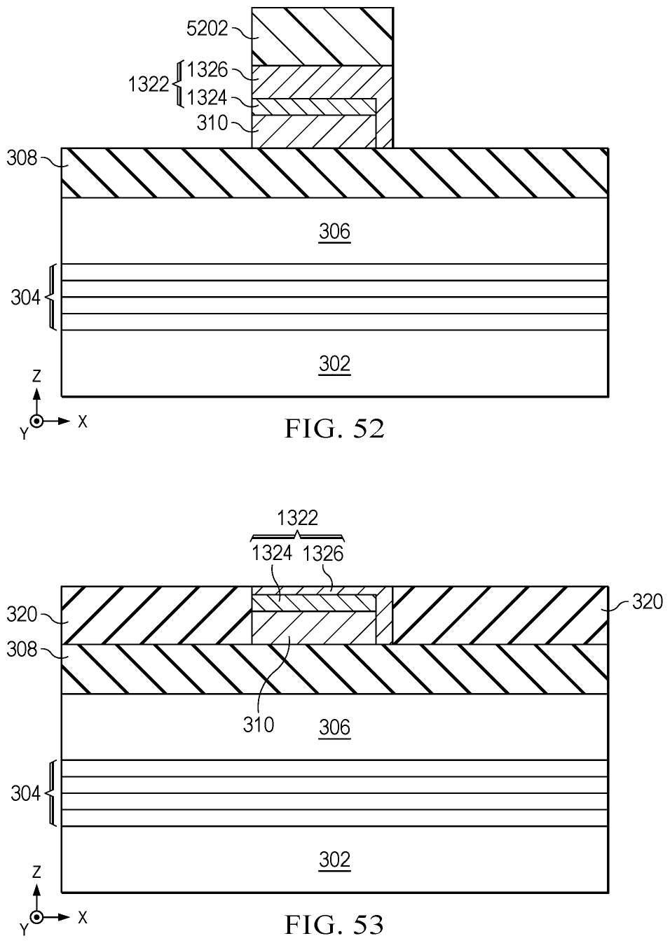

Referring to block 4906 and to FIG. 52, the first metal layer 1324 and the second metal layer 1326 are patterned into a gate electrical contact 1322, and the gate layer 310 is patterned. The first metal layer 1324, the second metal layer 1326, and the gate layer 310 may be patterned using appropriate photolithography and etch processes (e.g., using a photoresist 5202). The patterning of the second metal layer 1326, the first metal layer 1324, and the gate layer 310 may form the gate electrical contact 1322 to be self-aligned with the gate layer 310.

Referring to block 4908 and to FIG. 53, a first dielectric layer 320 is formed over and on the barrier layer 308 and along the gate electrical contact 1322. The gate electrical contact 1322 may be exposed through an upper surface of the first dielectric layer 320. The first dielectric layer 320 may be deposited using any appropriate deposition process. The material(s) of the first dielectric layer 320 may be as described above. The first dielectric layer 320 may be planarized, such as by a CMP, which may result in the gate electrical contact 1322 being exposed through the upper surface of the first dielectric layer 320. Processing continues at blocks 2022, 2024, 2026 as described with respect to FIG. 3.

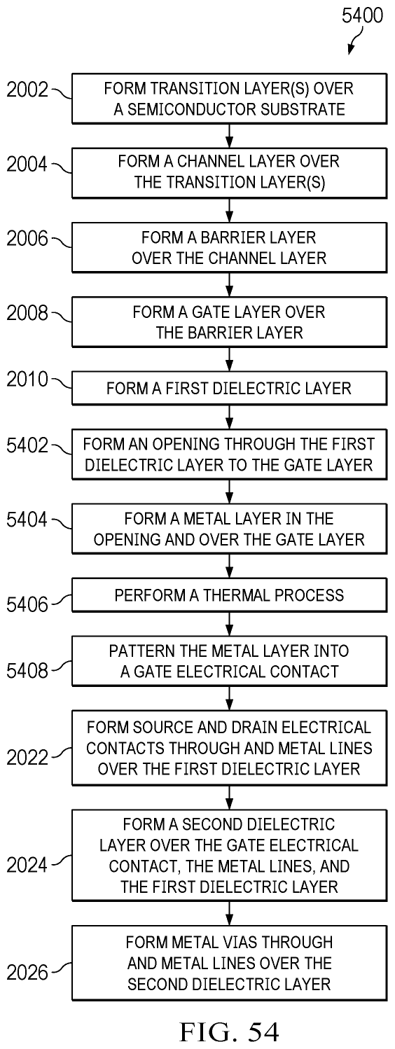

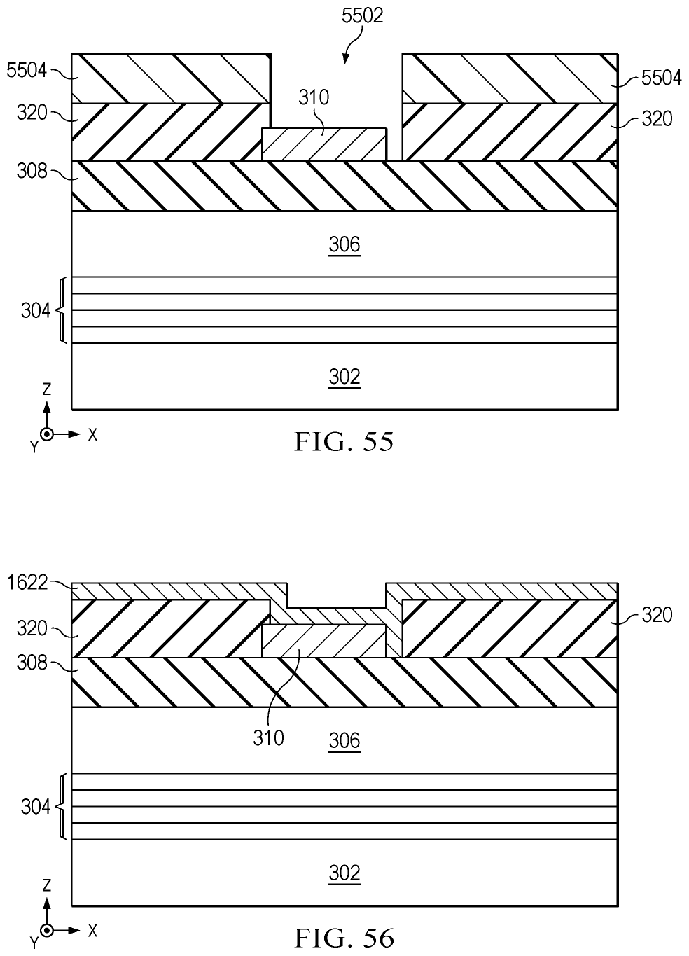

FIG. 54 is a flowchart of a method 5400 of manufacturing the semiconductor device 1600 of FIG. 16 according to some examples. The method 5400 of FIG. 54 is illustrated by and described in the context of FIGS. 55 through 57, which illustrate cross-sectional views of the semiconductor device 1600 at various stages of manufacturing.

Processing proceeds at blocks 2002, 2004, 2006, 2008, 2010 as described with respect to FIG. 21. Referring to block 5402 and to FIG. 55, an opening 5502 is formed through the first dielectric layer 320 to the gate layer 310. The opening 5502 is formed to and exposes the upper surface and a sidewall surface of the gate layer 310. The opening 5502 may be formed using appropriate photolithography and etch processes (e.g., using a photoresist 5504).

Referring to block 5404 and to FIG. 56, a metal layer 1622 is formed in the opening 5502, over and on the upper surface of the gate layer 310, and along the sidewall surface of the gate layer 310. The metal layer 1622 is conformally deposited over and on the upper surface of the first dielectric layer 320, along sidewall surfaces of the first dielectric layer 320 that define the opening 5502, and over and on the upper surface and sidewall surface of the gate layer 310 exposed by the opening 5502. The metal layer 1622 may be deposited using any appropriate deposition process. The metal layer 1622 may include or be a material as described above.

Referring to block 5406, a thermal process is performed. The thermal process may be an anneal process (e.g., high-temperature thermal annealing or laser annealing) or may be any process (such as a deposition or etch) that is performed at a high temperature. A process temperature of the thermal process may be greater than 600° C., such as in a range from 600° C. to 800° C. The thermal process may result in more spiking of the metal layer 1622 in the sidewall surface of the gate layer 310 compared to in the upper surface of the gate layer 310. The thermal process may be performed subsequently in the method 5400. The thermal process may also be performed to activate dopants, such as in the gate layer 310. The activation temperature may depend on how the dopant is introduced. For example, activation of dopants introduced by ion implantation may be performed at a higher temperature than dopants introduced during epitaxial growth.

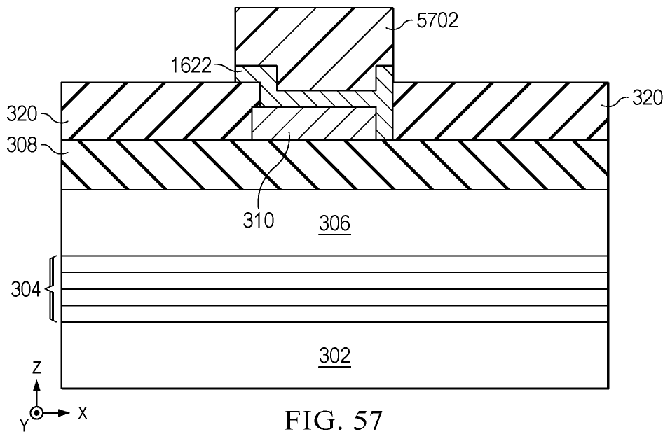

Referring to block 5408 and to FIG. 57, the metal layer 1622 is patterned into a gate electrical contact 1622. The metal layer 1622 may be patterned using appropriate photolithography and etch processes (e.g., using a photoresist 5702). Processing continues at blocks 2022, 2024, 2026 as described with respect to FIG. 3.

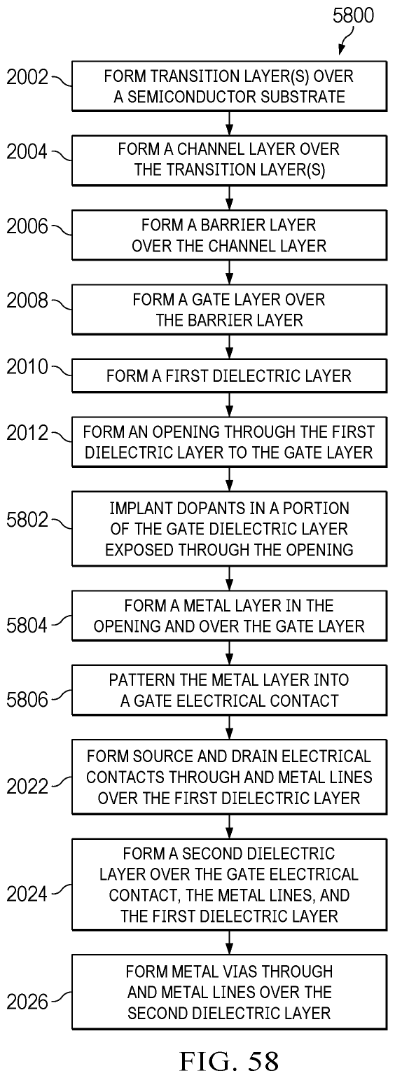

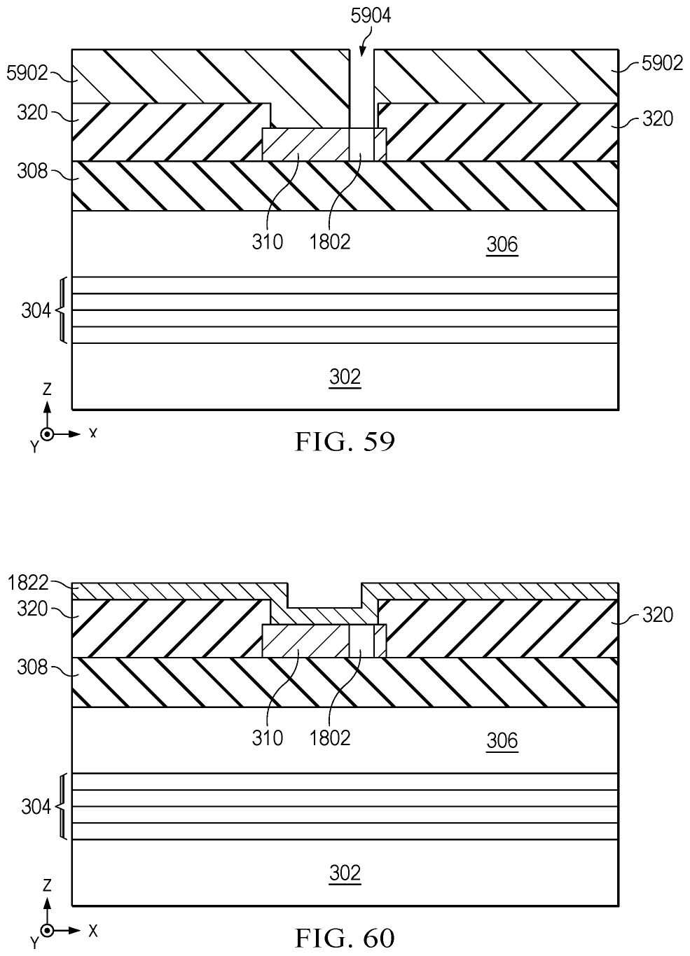

FIG. 58 is a flowchart of a method 5800 of manufacturing the semiconductor device 1800 of FIG. 18 according to some examples. The method 5800 of FIG. 58 is illustrated by and described in the context of FIGS. 59 through 61, which illustrate cross-sectional views of the semiconductor device 1800 at various stages of manufacturing.

Processing proceeds at blocks 2002, 2004, 2006, 2008, 2010, 2012 as described with respect to FIGS. 21 and 22. Referring to block 5802 and to FIG. 58, dopants are implanted into a portion of the gate layer 310 that is exposed through the opening 2202. Implanting the dopants forms the highly doped region 1802 in the gate layer 310. For example, to implant the dopants, a photoresist 5902 is deposited (e.g., by spin-on) over and/or on the semiconductor substrate 302 (e.g., over and/or on the gate layer 310 and the first dielectric layer 320) and patterned using photolithography. The photoresist 5902 is patterned with an opening 5904 to expose the portion of the gate layer 310 in which the highly doped region 1802 (which is further exposed through the opening 2202) is to be formed. With the patterned photoresist 5902, an implantation process is performed, using the patterned photoresist 5902 as a mask, to implant the dopants into the gate layer 310 to form the highly doped region 1802. After the implantation process, the photoresist 5902 is removed, such as by ashing. The dopant and concentration may be as described above. Implanting the highly doped region 1802 may permit easier formation of a low energy barrier height junction.

Referring to block 5804 and to FIG. 60, a metal layer 1822 is formed in the opening 2202 and over and on the upper surface of the gate layer 310. The metal layer 1822 is conformally deposited over and on the upper surface of the first dielectric layer 320, along sidewall surfaces of the first dielectric layer 320 that define the opening 2202, and over and on the upper surface of the gate layer 310 exposed by the opening 2202. The metal layer 1822 may be deposited using any appropriate deposition process. The metal layer 1822 may include or be a material as described above.

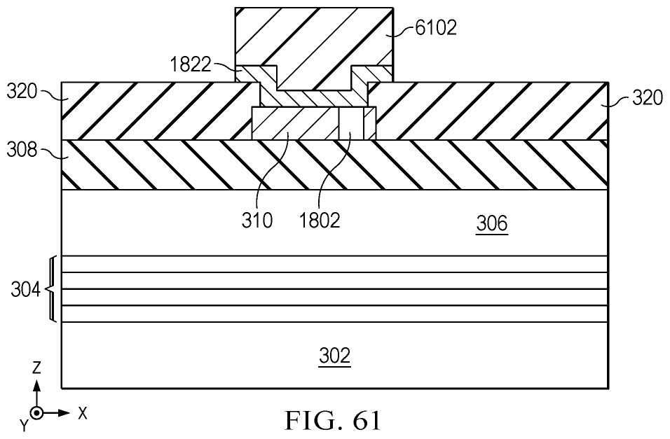

Referring to block 5806 and to FIG. 61, the metal layer 1822 is patterned into a gate electrical contact 1822. The metal layer 1822 may be patterned using appropriate photolithography and etch processes (e.g., using a photoresist 6102). The gate electrical contact 1822 may therefore be formed using a single metal deposition process and a single patterning process. Processing continues at blocks 2022, 2024, 2026 as described with respect to FIG. 3.

In any of the foregoing methods, source electrical contact 342 and drain electrical contact 344 can be formed after gate layer 310 is formed, in a gate first process, or before gate layer 310 is formed, in a gate last process. In such examples, block 2022 can be performed first, followed by forming an opening through first dielectric layer 320, and followed by forming the gate layer 310 via the opening.

Any of the foregoing methods may also be modified to form a dielectric layer 1902 as illustrated in FIG. 19. The dielectric layer 1902 may be deposited or formed on the gate layer 310 after depositing the gate layer 310 and before the deposition of a first metal layer. For example, the dielectric layer 1902 may be formed on the gate layer 310 in FIG. 21 (with the first dielectric layer 320 subsequently formed over and on the dielectric layer 1902) or in FIG. 34 (with the first metal layer 524 formed over and on the dielectric layer 1902). The dielectric layer 1902 may be deposited or formed by oxidation, PECVD, atomic layer deposition (ALD), or the like. Any etch to form an opening in which a first metal layer is to be formed may expose the dielectric layer 1902 rather than the gate layer 310 (e.g., in FIGS. 22 and 28) Any etch to expose a portion of the gate layer 310 after depositing a first metal layer and prior to forming a second metal layer (e.g., in FIGS. 24, 30, 35) may remove the dielectric layer 1902 from where the second metal layer contacts the gate layer 310. In some examples, an etch process may be performed before or after the implantation of FIG. 59 to remove the dielectric layer 1902 from where the second metal portion of the gate electrical contact contacts the gate layer 310, where the photoresist 5902 is further used as a mask for the etch process. In some examples, the second metal layer, or the second metal portion of the gate electrical contact, contacts a sidewall surface of the gate layer 310, and hence, no further etch to remove the dielectric layer 1902 may be necessary for the second metal layer, or the second metal portion, to contact the gate layer 310. Other modifications to the methods may be made.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

Although various examples have been described in detail, it should be understood that various changes, substitutions, and alterations can be made therein without departing from the scope defined by the appended claims.

What is claimed is:

1. A semiconductor device comprising:
a semiconductor substrate;
a drain electrical contact on the semiconductor substrate;
a source electrical contact on the semiconductor substrate;
a barrier layer over a channel region of the semiconductor substrate between the drain electrical contact and the source electrical contact;
a gate layer over the barrier layer, the gate layer including a first semiconductor portion and a second semiconductor portion; and
a gate electrical contact contacting the gate layer, the gate electrical contact including a first metal portion and a second metal portion, the first metal portion forming a first junction with the first semiconductor portion, the second metal portion forming a second junction with the second semiconductor portion, the first junction and the second junction having different energy barrier heights.

2. The semiconductor device of claim 1, wherein the first junction has a first energy barrier height, the second junction has a second energy barrier height, the first energy barrier height is at least 1.7 electron volt (eV), and the second energy barrier height is less than 1.7 eV.

3. The semiconductor device of claim 1, wherein:
the first junction is a Schottky junction; and
the second junction is an ohmic junction.

4. The semiconductor device of claim 1, wherein:
the first junction is a first Schottky junction; and
the second junction is a second Schottky junction.

5. The semiconductor device of claim 1, wherein the first metal portion includes a metal material different from a metal material of the second metal portion.

6. The semiconductor device of claim 5, wherein the first metal portion and the second metal portion include at least one of: titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), or titanium aluminum nitride (TiAlN).

7. The semiconductor device of claim 1, wherein the first metal portion and the second metal portion includes a same metal material, the metal material including at least one of: titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), or titanium aluminum nitride (TiAlN).

8. The semiconductor device of claim 5, wherein:
the first metal portion is over a first surface of the gate layer parallel with a surface of the barrier layer, the first metal portion being over the first semiconductor portion at the first surface; and
the second metal portion is over the first surface, the second metal portion contacting the second semiconductor portion at the first surface.

9. The semiconductor device of claim 8, wherein the second metal portion is laterally outside of an active area of the semiconductor substrate, the gate layer being on the active area.

10. The semiconductor device of claim 8, wherein:
the second metal portion is over the first surface proximate the source electrical contact; and
the source electrical contact is notched on a side proximate to the gate layer and in a channel length direction corresponding to where the second metal portion contacts the first surface.

11. The semiconductor device of claim 5, wherein:
the first metal portion is over a first surface of the gate layer parallel with a surface of the barrier layer, the first metal portion being over the first semiconductor portion at the first surface; and
the second metal portion is along a second surface of the gate layer facing a different direction from the first surface, the second metal portion contacting the second semiconductor portion at the second surface.

12. The semiconductor device of claim 11, wherein the second metal portion is laterally outside of an active area of the semiconductor substrate, the gate layer being on the active area.

13. The semiconductor device of claim 11, wherein:
the second surface is proximate to the source electrical contact; and
the source electrical contact is notched on a side proximate to the gate layer and in a channel length direction corresponding to where the second metal portion contacts the second surface.

14. The semiconductor device of claim 1, wherein:
the first metal portion and the second metal portion include a same metal material;
the first metal portion is over a first surface of the gate layer parallel with a surface of the barrier layer, the first metal portion being over the first semiconductor portion at the first surface; and
the second metal portion is along a second surface of the gate layer facing a different direction from the first surface, the second metal portion contacting the second semiconductor portion at the second surface.

15. The semiconductor device of claim 14, wherein the second metal portion is laterally outside of an active area of the semiconductor substrate, the gate layer being on the active area.

16. The semiconductor device of claim 1, wherein:
the first metal portion and the second metal portion include a same metal material;
the second semiconductor portion includes a dopant, a concentration of the dopant in the second semiconductor portion being greater than a concentration of the dopant in the first semiconductor portion;
the first metal portion is over a first surface of the gate layer parallel with a surface of the barrier layer, the first metal portion being over the first semiconductor portion at the first surface; and
the second metal portion is over the first surface, the second metal portion contacting the second semiconductor portion at the first surface.

17. The semiconductor device of claim 1, further comprising a dielectric layer between the first metal portion and the first semiconductor portion.

18. A method comprising:
forming a patterned gate layer over a barrier layer, the barrier layer being over a channel layer over a semiconductor substrate, the patterned gate layer comprising a first semiconductor portion and a second semiconductor portion; and
forming a gate electrical contact contacting the patterned gate layer, the gate electrical contact comprising a first metal portion and a second metal portion, a first energy barrier height being of a junction between the first metal portion and the first semiconductor portion, a second energy barrier height being of a junction between the second metal portion and the second semiconductor portion, the first energy barrier height being greater than the second energy barrier height.

19. The method of claim 18 further comprising:
forming a first dielectric layer over the patterned gate layer; and
forming a first opening through the first dielectric layer, the first opening being over the patterned gate layer, wherein forming the gate electrical contact includes:
forming a first metal layer in the first opening;
forming a second opening through the first metal layer to the patterned gate layer;
forming a second metal layer in the second opening and contacting the patterned gate layer; and
patterning the second metal layer and the first metal layer into the gate electrical contact, a remaining portion of the first metal layer being the first metal portion, a remaining portion of the second metal layer being the second metal portion.

20. The method of claim 19, wherein:
the first opening is to the patterned gate layer; and
the first metal layer in the first opening contacts the patterned gate layer.

21. The method of claim 19 further comprising forming a second dielectric layer over the patterned gate layer, wherein:
the first dielectric layer is formed over the second dielectric layer;
the first opening is to the second dielectric layer;
the first metal layer in the first opening contacts the second dielectric layer; and
the second opening is formed through the second dielectric layer.

22. The method of claim 18 further comprising:
forming a first dielectric layer over the patterned gate layer; and
forming a first opening through the first dielectric layer to the patterned gate layer and a second opening through the first dielectric layer, the first opening being over the patterned gate layer, the second opening being to the patterned gate layer, wherein forming the gate electrical contact includes:
forming a first metal layer in the first opening and the second opening;
removing the first metal layer from the second opening;
forming a second metal layer in the second opening and contacting the patterned gate layer; and
patterning the second metal layer and the first metal layer into the gate electrical contact, a remaining portion of the first metal layer being the first metal portion, a remaining portion of the second metal layer being the second metal portion.

23. The method of claim 22, wherein:
the first opening is to the patterned gate layer; and
the first metal layer in the first opening contacts the patterned gate layer.

24. The method of claim 22 further comprising forming a second dielectric layer over the patterned gate layer, wherein:
the first dielectric layer is formed over the second dielectric layer;
the first opening is to the second dielectric layer;
the first metal layer in the first opening contacts the second dielectric layer; and
removing the first metal layer from the second opening further removes the second dielectric layer exposed by the second opening.

25. The method of claim 18, wherein:
forming the patterned gate layer includes forming a gate layer;
forming the gate electrical contact includes:
forming a first metal layer over the gate layer;
patterning the first metal layer; and
forming a second metal layer over the gate layer and a remaining portion of the first metal layer; and
forming the patterned gate layer and the gate electrical contact includes patterning the second metal layer and the remaining portion of the first metal layer into the gate electrical contact and the gate layer into the patterned gate layer, a remaining patterned portion of the first metal layer being the first metal portion, a remaining patterned portion of the second metal layer being the second metal portion.

26. The method of claim 18 further comprising:
forming a dielectric layer over the patterned gate layer; and
forming a first opening through the dielectric layer to the patterned gate layer, the first opening exposing an upper surface of the patterned gate layer and a sidewall surface of the patterned gate layer, wherein forming the gate electrical contact includes:
forming a metal layer in the first opening, a first portion of the metal layer contacting the upper surface of the patterned gate layer, a second portion of the metal layer contacting the sidewall surface of the patterned gate layer; and
performing a thermal process on the metal layer, the first portion of the metal layer being the first metal portion, the second portion of the metal layer being the second metal portion.

27. The method of claim 18 further comprising:
forming a dielectric layer over the patterned gate layer;
forming an opening through the dielectric layer to the patterned gate layer; and
implanting a dopant into the second semiconductor portion of the patterned gate layer and through the opening, wherein forming the gate electrical contact includes forming a metal layer in the opening and contacting the patterned gate layer, the first metal portion including a first portion of the metal layer, the second metal portion including a second portion of the metal layer.
